(19) United States
(12) Patent Application Publication
(10) Pub. No.: US 2024/0074268 A1
(43) Pub. Date: Feb. 29, 2024

(54) DISPLAY PANEL AND DISPLAY DEVICE

(71) Applicant: Wuhan Tianma Micro-Electronics Co., Ltd., Wuhan, Hubei (CN)

(72) Inventor: Wei HUANG, Wuhan, Hubei (CN)

(73) Assignee: Wuhan Tianma Micro-Electronics Co., Ltd., Wuhan, Hubei (CN)

(21) Appl. No.: 17/791,286

(22) PCT Filed: Jun. 30, 2021
(86) PCT No.: PCT/CN2021/103392

§ 371 Date: Jul. 7, 2022

(30) Foreign Application Priority Data
Apr. 27, 2021 (CN) 202110462176.9

(51) Int. Cl. H10K 59/35; H10K 59/131; H10K 59/80

(52) U.S. Cl. CPC H10K 59/35; H10K 59/131; H10K 59/8051

(57) ABSTRACT

Provided are a display panel and a display device. The display panel includes a first display region and a second display region. The first display region includes a plurality of first sub-pixels. The second display region includes a plurality of second sub-pixels. The first sub-pixel includes a first-type first sub-pixel. The second sub-pixel includes a first-type second sub-pixel. The emitted color of the first-type first sub-pixel is the same as the emitted color of the first-type second sub-pixel. The first-type first sub-pixel includes a first anode. The first-type second sub-pixel includes a second anode. The area of the first anode is less than the area of the second anode.

This application claims priority to Chinese Patent Application No. 202110462176.9 filed with the China National Intellectual Property Administration (CNIPA) on Apr. 27, 2021, the disclosure of which is incorporated herein by reference in its entirety.

### TECHNICAL FIELD

The present application relates to the field of display technology, for example, a display panel and a display device.

### BACKGROUND

With the development of electronic products such as mobile phones including display panels and cameras, the requirements of people on these products have not only been limited to basic communication functions, but also turned to design, artistry and good visual experience. For example, electronic products with a high screen-to-body ratio become more and more popular. A full screen becomes an important development direction of electronic products. Earpieces, ambient light sensors and proximity light sensors have all been successfully hidden under a screen, but front-facing cameras are difficult to hide.

To achieve a true full screen, front-facing cameras may be disposed under a screen. However, many problems to be solved urgently exist when front-facing cameras are disposed under a full screen.

### SUMMARY

The present application provides a display panel and a display device to solve the problems of a full screen having a front-facing camera disposed under the screen.

The display panel includes a first display region and a second display region. The first display region includes a plurality of first sub-pixels. The second display region includes a plurality of second sub-pixels.

The first sub-pixel includes the first-type first sub-pixels. The second sub-pixel includes first-type second sub-pixel. The emitted color of the first-type first sub-pixel is the same as the emitted color of the first-type second sub-pixel.

A first-type first sub-pixel includes a first anode. A first-type second sub-pixel includes a second anode.

The area of the first anode is less than the area of the second anode.

The display device includes the preceding display panel.

### BRIEF DESCRIPTION OF DRAWINGS

FIG. 1 is a diagram illustrating a structure of a display panel according to an embodiment of the present application.

FIG. 2 is an enlarged view illustrating a structure of part A of FIG. 1.

FIG. 3 is a section view taken along direction B-B′ of FIG. 2.

FIG. 4 is a partial section view according to an embodiment of the present application.

FIG. 5 is another partial section view according to an embodiment of the present application.

FIG. 6 is a diagram illustrating a partial structure of a display panel according to an embodiment of the present application.

FIG. 7 is a diagram illustrating a partial structure of another display panel according to an embodiment of the present application.

FIG. 8 is an enlarged partial view of FIG. 7.

FIG. 9 is another partial section view according to an embodiment of the present application.

FIG. 10 is another partial section view according to an embodiment of the present application.

FIG. 11 is a diagram illustrating a partial structure of another display panel according to an embodiment of the present application.

FIG. 12 is a section view illustrating a partial structure of a display panel according to an embodiment of the present application.

FIG. 13 is a section view illustrating a partial structure of another display panel according to an embodiment of the present application.

FIG. 14 is a diagram illustrating a partial structure of another display panel according to an embodiment of the present application.

FIG. 15 is an enlarged partial view of FIG. 14.

FIG. 16 is a section view taken along direction C-C′ of FIG. 14.

FIG. 17 is a diagram illustrating the structure of a first pixel circuit according to an embodiment of the present application.

FIG. 18 is a diagram of circuit elements of a first pixel circuit according to an embodiment of the present application.

FIG. 19 is a section view illustrating a partial structure of another display panel according to an embodiment of the present application.

FIG. 20 is a diagram illustrating a partial structure of another display panel according to an embodiment of the present application.

FIG. 21 is an enlarged partial view of FIG. 20.

FIG. 22 is a section view taken along direction D-D′ of FIG. 20.

FIG. 23 is a diagram illustrating a partial structure of another display panel according to an embodiment of the present application.

FIG. 24 is an enlarged partial view of FIG. 23.

FIG. 25 is a diagram illustrating a partial structure of another display panel according to an embodiment of the present application.

FIG. 26 is an enlarged partial view of FIG. 25.

FIG. 27 is a section view taken along direction G-G′ of FIG. 25.

FIG. 28 is a diagram illustrating the structure of another display panel according to an embodiment of the present application.

FIG. 29 is an enlarged view illustrating the structure of part H of FIG. 28.

FIG. 30 is a section view illustrating a partial structure of another display panel according to an embodiment of the present application.

FIG. 31 is a section view illustrating a partial structure of another display panel according to an embodiment of the present application.

FIG. 32 is a diagram illustrating the structure of another first pixel circuit according to an embodiment of the present application.

FIG. 33 is a diagram of circuit elements of another first pixel circuit according to an embodiment of the present application.

FIG. 34 is a section view illustrating a partial structure of another display panel according to an embodiment of the present application.

FIG. 35 is a section view illustrating a partial structure of another display panel according to an embodiment of the present application.

FIG. 36 is a diagram illustrating the structure of a display device according to an embodiment of the present application.

FIG. 37 is a section view illustrating the structure of a display device according to an embodiment of the present application.

### DETAILED DESCRIPTION

The present application is described below in conjunction with drawings and embodiments. The embodiments described herein are merely intended to explain the present application and not to limit the present application. For ease of description, only part, not all, of structures related to the present application are illustrated in the drawings.

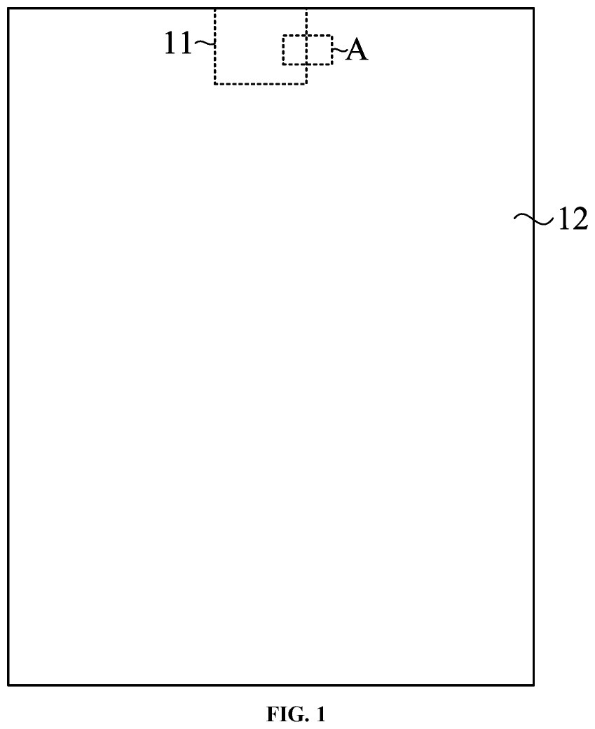

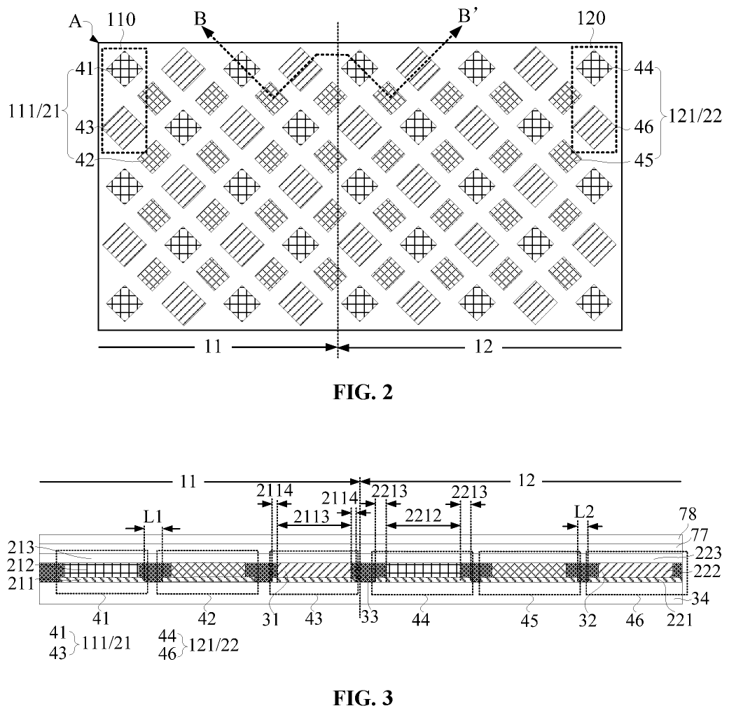

FIG. 1 is a diagram illustrating a structure of a display panel according to an embodiment of the present application. FIG. 2 is an enlarged view illustrating a structure of part A of FIG. 1. FIG. 3 is a section view taken along direction B-B′ of FIG. 2. As shown in FIGS. 1 to 3, the display panel according to this embodiment of the present application includes a first display region 11 and a second display region 12. The first display region 11 includes a plurality of first sub-pixels 111. The second display region 12 includes a plurality of second sub-pixels 121. The first sub-pixel 111 includes the first-type first sub-pixel 21. The second sub-pixel 121 includes the first-type second sub-pixel 22. The emitted color of the first-type first sub-pixel 21 is the same as the emitted color of the first-type second sub-pixel 22. The first-type first sub-pixel 21 includes a first anode 211. The first-type second sub-pixel 22 includes a second anode 221. The area of the first anode 211 is less than the area of the second anode 221.

As shown in FIGS. 1 to 3, the display panel according to this embodiment of the present application is applicable to a display device having a sensor disposed under a screen. The display panel includes the first display region 11 and the second display region 12. The first display region 11 may also serve as the disposition region of the sensor. The sensor may be a device such as a camera and an infrared sensor. This is not limited in this embodiment of the present application.

With continued reference to FIGS. 1 to 3, for example, the first display region 11 includes a plurality of first sub-pixels 111 arranged in an array. The first-type first sub-pixel 21 in a first sub-pixel 111 includes a first anode 211, a first organic light-emitting layer 212 and a first cathode 213 sequentially stacked on a side of an array substrate 34. An electron and a hole are injected from the first cathode 213 and the first anode 211 into the first organic light-emitting layer 212 separately, and then an exciton is formed in the first organic light-emitting layer 212 to excite a light-emitting molecule. In this manner, the first light-emitting layer 212 may emit visible light.

With continued reference to FIGS. 1 to 3, for example, the second display region 12 includes a plurality of second sub-pixels 121 arranged in an array. The first-type second sub-pixel 22 in a second sub-pixel 121 includes a second anode 221, a second organic light-emitting layer 222 and a second cathode 223 sequentially stacked. An electron and a hole are injected from the second cathode 223 and the second anode 221 into the second organic light-emitting layer 222 separately, and then an exciton is formed in the second organic light-emitting layer 222 to excite a light-emitting molecule. In this manner, the second light-emitting layer 222 may emit visible light.

The first cathode 213 and the second cathode 223 may be the same conductive film layer and may be configured according to actual requirements.

To ensure that the sensor of the first display region 11 can receive enough external natural light, the first display region 11 is generally provided with a large light-transmissive region. For example, the number of first sub-pixels 111 is reduced to increase the area of the light-transmissive region. However, the reduction of the number of first sub-pixels 111 may reduce the brightness of the first display region 11. As a result, there is a brightness difference between the first display region 11 and the second display region 12. To reduce the brightness difference between the first display region 11 and the second display region 12, the drive current of a first sub-pixel 111 may be increased to increase the brightness of the first display region 11. However, the increase of the drive current of the first sub-pixel 111 may cause a leakage current between the first anodes 211 of adjacent first sub-pixels 111. Since the first sub-pixel 111 may emit light under the driving of a small amount of the drive current, the leakage current leaking from the first anode 211 of one first sub-pixel 111 to the first anode 211 of another adjacent first sub-pixel 111 may cause the adjacent first sub-pixel 111 to emit light, thereby causing the adjacent first sub-pixel 111 that should not emit light to emit light. As a result, the problem of leakage emission is formed. The problem of leakage emission not only affects the image display effect of the display panel, but also increases the power consumption of the display panel and reduces the service life of the display panel. Thus, in this embodiment, the area of the first anode 211 of the first-type first sub-pixel 21 is configured to be less than the area of the second anode 221 of the first-type second sub-pixel 22 to increase the spacing between the first anodes 211 of adjacent first-type first sub-pixels 21. In this manner, the problem of leakage emission of an adjacent first sub-pixel 111 is alleviated, the image display effect of the display panel is improved, and the service life of the display panel is prolonged.

In summary, in the display panel provided by this embodiment of the present application, the first-type first sub-pixels 21 are disposed in the first display region 11; the first-type second sub-pixels 22 having the same emitted colors as the emitted colors of the first-type first sub-pixels 21 are disposed in the second display region 12; and the area of the first anode 211 of a first-type first sub-pixel 21 is configured to be less than the area of the second anode 221 of a first-type second sub-pixel 22 to increase the spacing between the first anodes 211 of the adjacent first-type first sub-pixels 21. In this manner, the problem of leakage emission of an adjacent first sub-pixel 111 is alleviated, the image display effect of the display panel is improved, and the service life of the display panel is prolonged.

With continued reference to FIGS. 1 to 3, optionally, the first-type first sub-pixel 21 also includes a first pixel opening 31. The first-type second sub-pixel 22 also includes a second pixel opening 32. The first anode 211 includes a first anode effective region 2113. The vertical projection of the first pixel opening 31 on the plane where the first anode 211 is located covers the first anode effective region 2113. The second anode 221 includes a second anode effective region 2212. The vertical projection of the second pixel opening 32 on the plane where the second anode 221 is located covers the second anode effective region 2212. The area of the first anode effective region 2113 is less than the area of the second anode effective region 2212.

As shown in FIG. 3, the first anode effective region 2113 is the disposition region of the first organic light-emitting layer 212, and the second anode effective region 2212 is the disposition region of the second organic light-emitting layer 222. In this embodiment, the area of the first anode effective region 2113 is less than the area of the second anode effective region 2212 to increase the spacing between the first anode effective regions 2113 of the adjacent first-type first sub-pixels 21. In this manner, the problem of leakage emission of an adjacent first sub-pixel 111 is alleviated, the image display effect of the display panel is improved, and the service life of the display panel is prolonged.

With continued reference to FIGS. 1 to 3, optionally, the first-type first sub-pixel 21 also includes a first pixel opening 31. The first-type second sub-pixel 22 also includes a second pixel opening 32. The first anode 211 includes a first anode ineffective region 2114. The vertical projection of the first pixel opening 31 on the plane where the first anode 211 is located does not overlap the first anode ineffective region 2114. The second anode 221 includes a second anode ineffective region 2213. The vertical projection of the second pixel opening 32 on the plane where the second anode 221 is located does not overlap the second anode ineffective region 2213. The area of the first anode ineffective region 2114 is less than the area of the second anode ineffective region 2213.

As shown in FIG. 3, in the thickness direction of the display panel, the first anode ineffective region 2114 does not overlap the first organic light-emitting layer 212. Optionally, the first anode ineffective region 2114 is disposed around the first anode effective region 2113. The second anode ineffective region 2213 does not overlap the second organic light-emitting layer 222. Optionally, the second anode ineffective region 2213 is disposed around the second anode effective region 2212.

In this embodiment, the area of the first anode ineffective region 2114 is less than the area of the second anode ineffective region 2213 to increase the spacing between the first anodes 211 of the adjacent first-type first sub-pixels 21. In this manner, the problem of leakage emission of an adjacent first sub-pixel 111 is alleviated, the image display effect of the display panel is improved, and the service life of the display panel is prolonged.

With continued reference to FIGS. 2 and 3, optionally, the first display region 11 also includes a plurality of first pixel units 110. A first pixel unit 110 includes at least two first-type first sub-pixels 21 having different emitted colors. The second display region 12 also includes a plurality of second pixel units 120. A second pixel unit 120 includes at least two first-type second sub-pixels 22 having different emitted colors. The distance between two adjacent first-type first sub-pixels 21 in the same first pixel unit 110 is L1, the distance between two adjacent first-type second sub-pixels 22 in the same second pixel unit 120 is L2, and (L1−L2)/L2≥5%.

As shown in FIGS. 2 and 3, for example, the first pixel unit 110 includes two first-type first sub-pixels having different emitted colors, and the second pixel unit 120 includes two first-type second sub-pixels having different emitted colors. Distance L1 between the two adjacent first-type first sub-pixels 21 in the same first pixel unit 110 and distance L2 between the two adjacent first-type second sub-pixels 22 in the same second pixel unit 120 are configured to satisfy (L1−L2)/L2≥5% to ensure that distance L1 between the two adjacent first-type first sub-pixels 21 in the same first pixel unit 110 is greater, thereby increasing the spacing between the adjacent first-type first sub-pixels 21. In this manner, the problem of leakage emission of an adjacent first sub-pixel 111 is alleviated, the image display effect of the display panel is improved, and the service life of the display panel is prolonged.

In other embodiments, a first pixel unit 110 may include more first-type first sub-pixels 21 having different emitted colors, and a second pixel unit 120 may also include more first-type second sub-pixels 22 having different emitted colors. For example, the first pixel unit 110 may include three first-type first sub-pixels 21 having different emitted colors, and the second pixel unit 120 may also include three first-type second sub-pixels 22 having different emitted colors. The configuration may be according to actual requirements.

With continued reference to FIGS. 1 to 3, optionally, the pixel distribution density of the first sub-pixels 111 is greater than or equal to the pixel distribution density of the second sub-pixels 121.

The pixel distribution density refers to the number of sub-pixels per unit area.

As shown in FIG. 2, for example, the pixel distribution density of the first sub-pixels 111 is equal to the pixel distribution density of the second sub-pixels 121. The pixel distribution density of the first sub-pixels 111 is configured to be at least equal to the pixel distribution density of the second sub-pixels 121 to ensure that the number of first sub-pixels 111 per unit area of the first display region 11 is at least equal to the number of second sub-pixels 121 per unit area of the second display region 12, thereby reducing the brightness loss that may be caused by a small first anode effective region 2113. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

In other embodiments, the pixel distribution density of the first sub-pixels 111 may also be configured to be greater than the pixel distribution density of the second sub-pixels 121 to compensate for the brightness loss that may be caused by the small first anode effective region 2113. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

With continued reference to FIGS. 1 to 3, optionally, the pixel distribution density of the first sub-pixels 111 is the same as the pixel distribution density of the second sub-pixels 121.

As shown in FIG. 2, the pixel distribution density of the first sub-pixels 111 is configured to be the same as the pixel distribution density of the second sub-pixels 121 to reduce the visual effect difference between the first display region 11 and the second display region 12, thereby optimizing the display effect. Additionally, with the configuration in which the pixel distribution density of the first sub-pixels 111 is the same as the pixel distribution density of the second sub-pixels 121, the arrangement and design of pixel circuits and signal lines are simple and easy to implement.

FIG. 4 is an enlarged partial section view according to an embodiment of the present application. With continued reference to FIGS. 1 to 4, optionally, the first-type first sub-pixel 21 also includes a first pixel opening 31. The first-type second sub-pixel 22 also includes a second pixel opening 32. The first anode 211 includes a first anode effective region 2113. The vertical projection of the first pixel opening 31 on the plane where the first anode 211 is located covers the first anode effective region 2113. The second anode 221 includes a second anode effective region 2212. The vertical projection of the second pixel opening 32 on the plane where the second anode 221 is located covers the second anode effective region 2212. The area of the first anode effective region 2113 is less than the area of the second anode effective region 2212. The area of the first pixel opening 31 is less than or equal to the area of the second pixel opening 32.

As shown in FIGS. 3 and 4, the display panel also includes a pixel defining layer 33. Each of the first pixel opening 31 and the second pixel opening 32 is a pixel opening disposed on the pixel defining layer 33. The first pixel opening 31 is located in the first display region 11. The first organic light-emitting layer 212 is located in the first pixel opening 31. The second pixel opening 32 is located in the second display region 12. The second organic light-emitting layer 222 is located in the second pixel opening 32. Thus, the region where the first pixel opening 31 is located is the region where the first organic light-emitting layer 212 is located, and the region where the second pixel opening 32 is located is the region where the second organic light-emitting layer 222 is located.

As shown in FIGS. 3 and 4, for example, the area of the first pixel opening 31 is equal to the area of the second pixel opening 32. The area of the first pixel opening 31 is configured to be equal to the area of the second pixel opening 32 to reduce the difference between the visual effect of the first display region 11 and the visual effect of the second display region 12, thereby improving the display effect of the display panel.

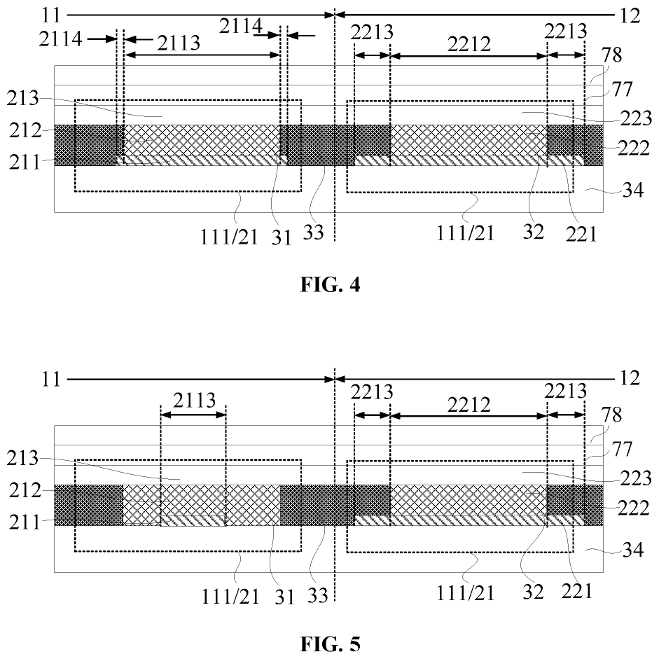

The area of the first anode effective region 2113 may be equal to the area of the first pixel opening 31 (as shown in FIG. 4). In other embodiments, the area of the first anode effective region 2113 may also be less than the area of the first pixel opening 31. For example, FIG. 5 is another enlarged partial section view according to an embodiment of the present application. As shown in FIG. 5, the area of the first anode effective region 2113 is less than the area of the first pixel opening 31. The configuration may be according to actual requirements.

The area of the first pixel opening 31 and the area of the second pixel opening 32 may be configured according to actual requirements. For example, the area of the first pixel opening 31 is ½ of the area of the second pixel opening 32. This is not limited in this embodiment of the present application.

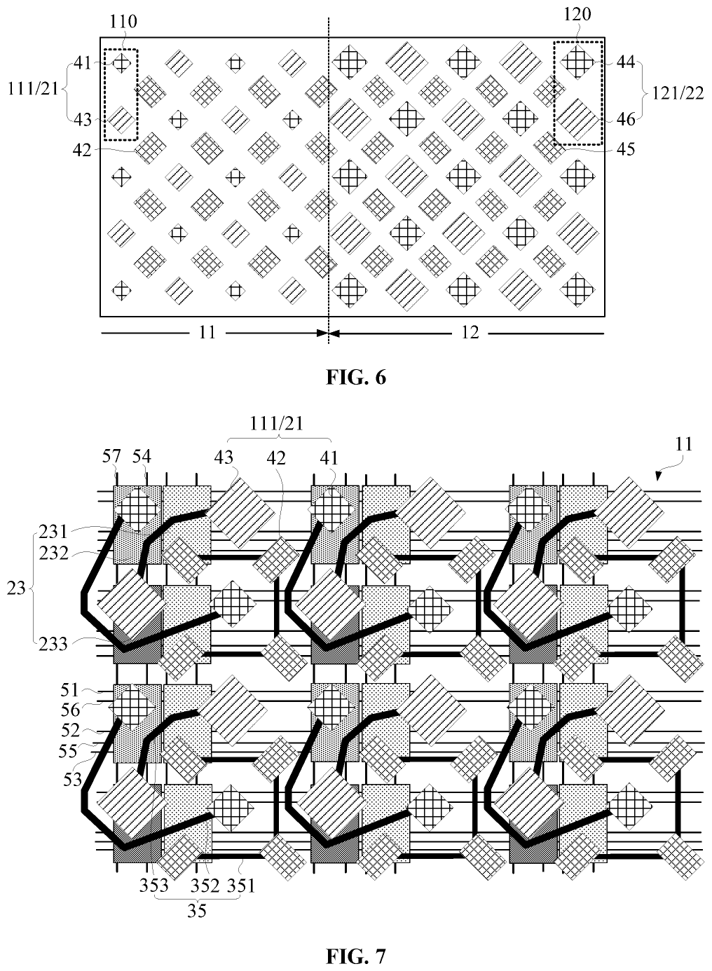

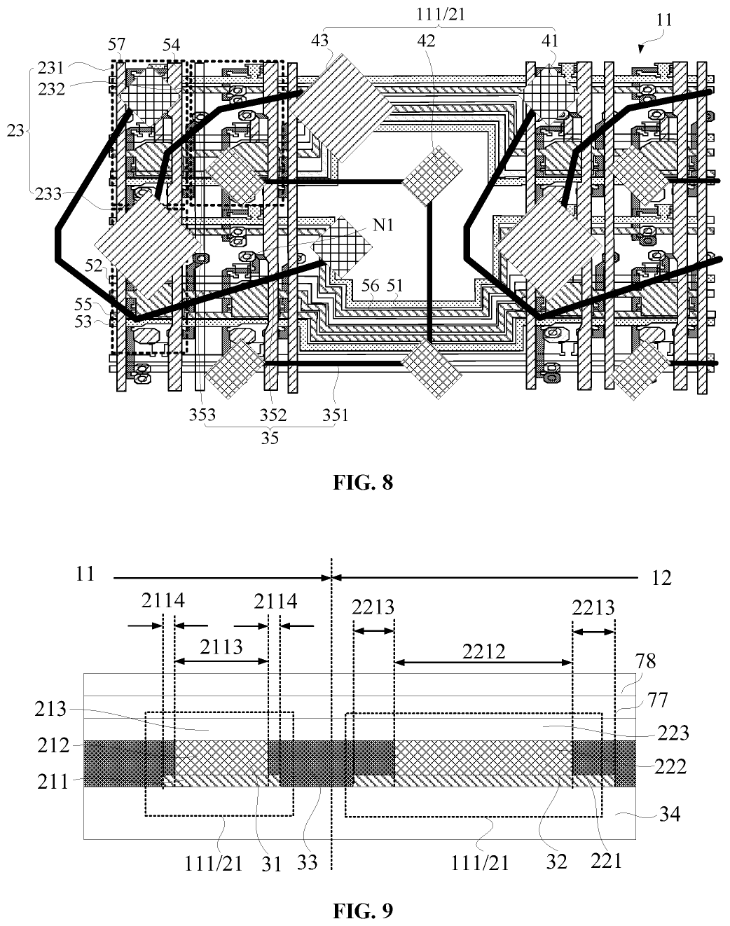

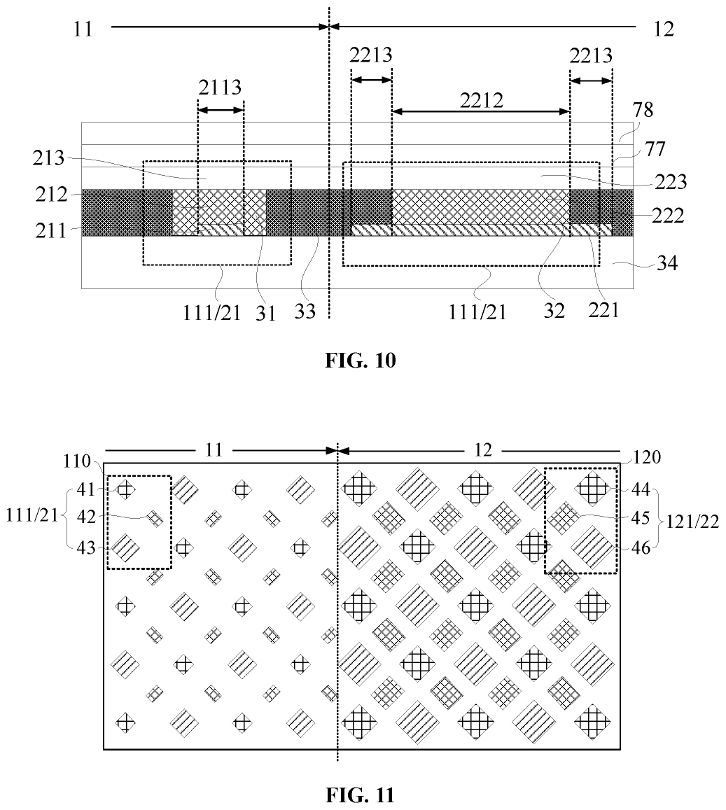

For example, FIG. 6 is a diagram illustrating a partial structure of a display panel according to an embodiment of the present application. FIG. 7 is a diagram illustrating a partial structure of another display panel according to an embodiment of the present application. FIG. 8 is an enlarged partial view of FIG. 7. FIG. 9 is another partial section view according to an embodiment of the present application. FIG. 10 is another partial section view according to an embodiment of the present application. As shown in FIGS. 6 to 10, the area of the first pixel opening 31 may also be less than the area of the second pixel opening 32 to reduce the area of the first anode effective region 2113. In this manner, the area of the first anode effective region 2113 is less than the area of the second anode effective region 2212, and the spacing between the first anode effective regions 2113 of the adjacent first-type first sub-pixels 21 is increased. Thus, the problem of leakage emission of an adjacent first sub-pixel 111 is alleviated, the image display effect of the display panel is improved, and the service life of the display panel is prolonged.

With continued reference to FIGS. 2 and 3, optionally, the first sub-pixel 111 includes the first red sub-pixel 41, the first green sub-pixel 42 and the first blue sub-pixel 43. The first-type first sub-pixel 21 includes the first red sub-pixel 41 and/or the first blue sub-pixel 43.

For example, as shown in FIGS. 2 and 3, the first sub-pixel 111 located in the first display region 11 includes the first red sub-pixel 41, the first green sub-pixel 42 and the first blue sub-pixel 43 to implement the color display of the first display region 11. The second sub-pixel 121 located in the second display region 12 includes the second red sub-pixel 44, the second green sub-pixel 45 and the second blue sub-pixel 46 to implement the color display of the second display region 12.

As shown in FIGS. 2 and 3, in this embodiment, the first-type first sub-pixels 21 is configured to include the first red sub-pixel 41 and/or the first blue sub-pixel 43. That is, the area of the first anode effective region 2113 of the first red sub-pixel 41 is configured to be less than the area of the second anode effective region 2212 of the second red sub-pixel 44, and/or the area of the first anode effective region 2113 of the first blue sub-pixel 43 is configured to be less than the area of the second anode effective region 2212 of the second blue sub-pixel 46 to reduce the area of the first anode effective region 2113 of the first red sub-pixel 41 and/or reduce the area of the first anode effective region 2113 of the first blue sub-pixel 43. Then the distance between the first anode effective region 2113 of the first red sub-pixel 41 and the first anode effective region 2113 of the first-type first sub-pixel 21 adjacent to the first anode effective region 2113 of the first red sub-pixel 41 is increased, and/or the distance between the first anode effective region 2113 of the first blue sub-pixel 43 and the first anode effective region 2113 of the first-type first sub-pixel 21 adjacent to the first anode effective region 2113 of the first blue sub-pixel 43 is increased. In this manner, the problem of leakage emission of the first red sub-pixel 41 and/or the first blue sub-pixel 43 is alleviated, the image display effect of the display panel is improved, and the service life of the display panel is prolonged.

As shown in FIGS. 2 and 3, for example, the first-type first sub-pixel 21 includes only the first red sub-pixel 41 and the first blue sub-pixel 43. In other embodiments, the first-type first sub-pixel 21 may include only the first red sub-pixel 41. Alternatively, the first-type first sub-pixel 21 may include only the blue sub-pixel 43. The configuration may be according to actual requirements.

With continued reference to FIGS. 2 and 3, optionally, the area of the first anode effective region 2113 of the first green sub-pixel 42 is equal to the area of the second anode effective region 2212 of the second green sub-pixel 45

Under the same brightness, human eyes are most sensitive to green, but insensitive to blue and red. For this reason, the area of the first anode effective region 2113 of the first green sub-pixel 42 is configured to be equal to the area of the second anode effective region 2212 of the second green sub-pixel 45 to ensure the brightness of the first green sub-pixel 42. In this manner, the difference between the visual effect of the first display region 11 and the visual effect of the second display region 12 is reduced, the phenomenon of uneven display brightness in the visual effect of the first display region 11 and the second display region 12 is alleviated, and the display effect of the display panel is improved.

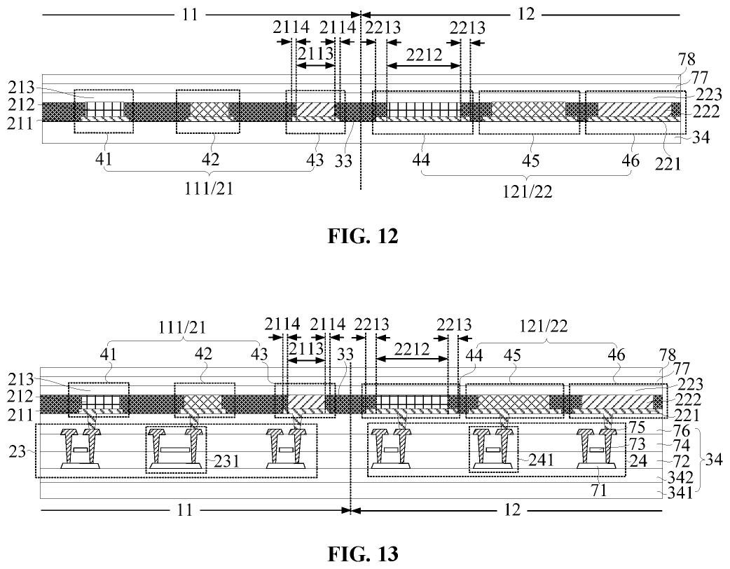

FIG. 11 is a diagram illustrating a partial structure of another display panel according to an embodiment of the present application. FIG. 12 is a section view illustrating a partial structure of a display panel according to an embodiment of the present application. As shown in FIGS. 11 and 12, on the basis of the preceding embodiments, optionally, the first-type first sub-pixels 21 also include green sub-pixels 42.

As shown in FIGS. 11 and 12, the first-type first sub-pixel 21 is configured to also include the green sub-pixel 42. That is, the area of the first anode effective region 2113 of the first green sub-pixel 42 is configured to be less than the area of the second anode effective region 2212 of the second green sub-pixel 45 to reduce the area of the first anode effective region 2113 of the first green sub-pixel 42. Then the distance between the first anode effective region 2113 of the first green sub-pixel 42 and the first anode effective region 2113 of the first-type first sub-pixel 21 adjacent to the first anode effective region 2113 of the first green sub-pixel 43 is increased. In this manner, the problem of leakage emission of the first green sub-pixel 42 is alleviated, the image display effect of the display panel is improved, and the service life of the display panel is prolonged.

FIG. 13 is a section view illustrating a partial structure of another display panel according to an embodiment of the present application. On the basis of the preceding embodiments, optionally, the first display region 11 also includes a plurality of first pixel circuits 23. The second display region 12 also includes a plurality of second pixel circuits 24. The first pixel circuit 23 is configured to drive the first sub-pixel 111 to emit light. The second pixel circuit 24 is configured to drive the second sub-pixel 121 to emit light. The second sub-pixel 121 includes the second green sub-pixel 45. The first pixel circuit 23 includes the first sub-pixel circuit 231 configured to drive the first green sub-pixel 42 to emit light. The second pixel circuit 24 includes the second sub-pixel circuit 241 configured to drive the second green sub-pixel 45 to emit light. The channel width-to-length ratio of the drive transistor in the first sub-pixel circuit 231 is greater than the channel width-to-length ratio of the drive transistor in the second sub-pixel circuit 241.

As shown in FIG. 13, the first pixel circuits 23 and the second pixel circuits 24 are disposed in the array substrate 34. The first pixel circuit 23 includes the first sub-pixel circuit 231. The drive transistor in the first sub-pixel circuit 231 forms the drive current to drive the first green sub-pixel 42 to emit light. The second pixel circuit 24 includes the second sub-pixel circuit 241. The drive transistor in the second sub-pixel circuit 241 forms the drive current to drive the second green sub-pixel 45 to emit light.

The magnitude of the drive current formed by the drive transistor depends on the channel width-to-length ratio of the drive transistor. The channel width-to-length ratio refers to the ratio of the channel width to the channel length of the drive transistor. The channel width-to-length ratio is increased to effectively reduce the on resistance of the drive transistor, thereby increasing the on current of the drive transistor, that is, the drive current of the drive transistor. The greater the drive current is, the greater the brightness of the driven sub-pixel is.

In this embodiment, the channel width-to-length ratio of the drive transistor in the first sub-pixel circuit 231 is configured to be greater than the channel width-to-length ratio of the drive transistor in the second sub-pixel circuit 241 to improve the brightness of the first green sub-pixel 42, thereby compensating for the brightness loss that may be caused by the small first anode effective region 2113 of the first green sub-pixel 42. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

In FIG. 13, only one thin-film transistor is used to illustrate the first pixel circuit 23 and the second pixel circuit 24. In actual conditions, each of the first pixel circuit 23 and the second pixel circuit 24 may include multiple thin-film transistors and may be configured according to actual requirements. This is not limited in this embodiment of the present application.

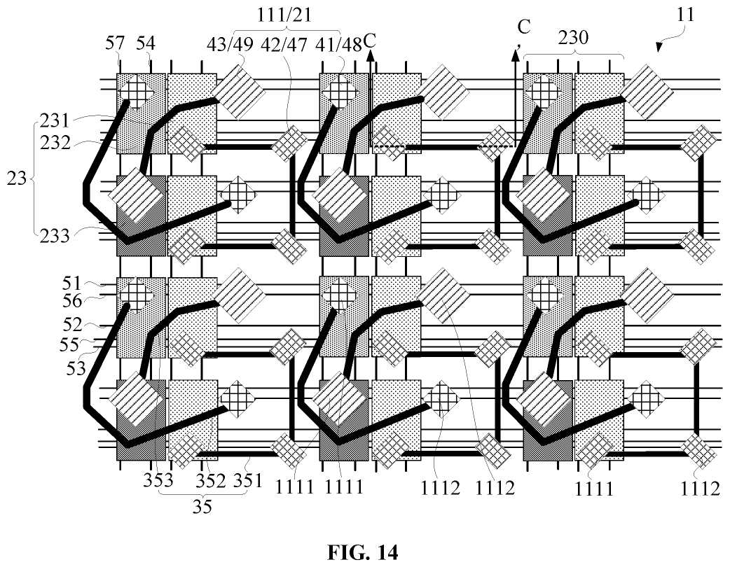

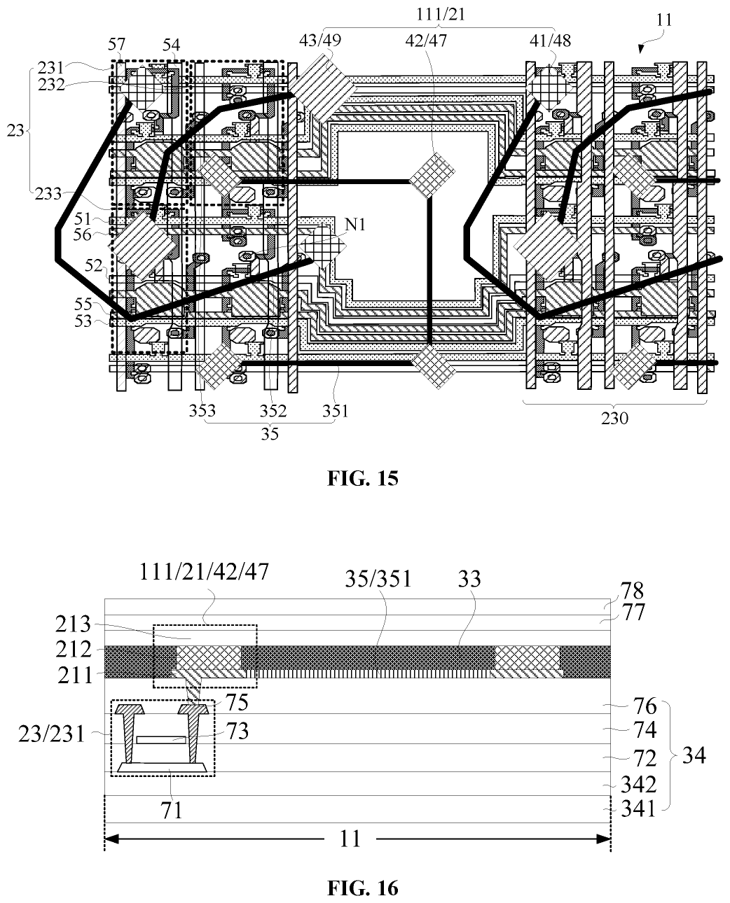

FIG. 14 is a diagram illustrating a partial structure of another display panel according to an embodiment of the present application. FIG. 15 is an enlarged partial view of FIG. 14. FIG. 16 is a section view taken along direction C-C′ of FIG. 14. As shown in FIGS. 14 to 16, optionally, the first sub-pixel circuit 231 is configured to drive at least two first green sub-pixels 42 to emit light.

As shown in FIGS. 14 to 16, the first sub-pixel circuit 231 is connected to at least two first green sub-pixels 42 through the first anode 211. In this manner, one first sub-pixel circuit 231 drives at least two first green sub-pixels 42 to emit light. In this embodiment, the first sub-pixel circuit 231 is configured to drive at least two first green sub-pixels 42 to emit light to reduce the number of first sub-pixel circuits 231, thereby improving the transmittance of the first display region 11. In this manner, the sensor disposed at the first display region 11 can receive more external natural light, and the service performance of the sensor is improved.

The number of first green sub-pixels 42 driven by one first sub-pixel circuit 231 may be configured according to actual requirements. For example, 1 is used to drive 2 (that is, one first sub-pixel circuit 231 is used to drive two first green sub-pixels 42), 1 is used to drive 3, and 1 is used to drive 4 to reduce the number of first sub-pixel circuits 231. This is not limited in this embodiment of the present application.

With continued reference to FIGS. 14 to 16, optionally, two first sub-pixel circuits 231 are configured to drive four first green sub-pixels 42 to emit light.

As shown in FIGS. 14 to 16, the two first sub-pixel circuits 231 are connected to the four first green sub-pixels 42 to make the two first sub-pixel circuits 231 drive the four first green sub-pixels 42 to emit light. In this embodiment, the two first sub-pixel circuits 231 are configured to drive the four first green sub-pixels 42 to emit light to reduce the number of first sub-pixel circuits 231 and take into account the drive load of the first sub-pixel circuit 231 at the same time, thereby improving the transmittance of the first display region 11 and ensuring the brightness of the first green sub-pixel 42 at the same time. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

With continued reference to FIG. 14, optionally, the first pixel circuit 23 also includes the third sub-pixel circuit 232 and the fourth sub-pixel circuit 233. The third sub-pixel circuit 232 is configured to drive the first red sub-pixel 41 to emit light. The fourth sub-pixel circuit 233 is configured to drive the first blue sub-pixel 43 to emit light. A third sub-pixel circuit 232 is configured to drive at least two first red sub-pixels 41 to emit light. Moreover/Alternatively, a fourth sub-pixel circuit 233 is configured to drive at least two first blue sub-pixels 43 to emit light.

As shown in FIG. 14, one third sub-pixel circuit 232 is connected to at least two first red sub-pixels 41 to make the one third sub-pixel circuit 232 drive the at least two first red sub-pixels 41 to emit light. One fourth sub-pixel circuit 233 is connected to at least two first blue sub-pixels 43 to make the one fourth sub-pixel circuit 233 drive the at least two first blue sub-pixels 43 to emit light. In this embodiment, the third sub-pixel circuit 232 is configured to drive at least two first red sub-pixels 41 to emit light, and/or the fourth sub-pixel circuit 233 is configured to drive at least two first blue sub-pixels 43 to emit light to reduce the number of third sub-pixel circuits 232 and/or reduce the number of fourth sub-pixel circuits 233, thereby improving the transmittance of the first display region 11. In this manner, the sensor disposed at the first display region 11 can receive more external natural light, and the service performance of the sensor is improved.

The description is given with reference to FIG. 14 by using an example in which the third sub-pixel circuit 232 drives at least two first red sub-pixels 41 to emit light, and the fourth sub-pixel circuit 233 drives at least two first blue sub-pixels 43 to emit light. In other embodiments, the third sub-pixel circuit 232 is configured to drive only at least two first red sub-pixels 41 to emit light, or the fourth sub-pixel circuit 233 is configured to drive only at least two first blue sub-pixels 43 to emit light.

Moreover, each of the number of first red sub-pixels 41 driven by one third sub-pixel circuit 232 and the number of first blue sub-pixels 43 driven by one fourth sub-pixel circuit 233 may be configured according to actual requirements. This is not limited in this embodiment of the present application.

With continued reference to FIGS. 14 to 16, optionally, the first display region 11 also includes a plurality of first pixel circuits 23. The first pixel circuit 23 is configured to drive the first sub-pixel 111 to emit light. The first pixel circuit 23 includes the first sub-pixel circuit 231, the third sub-pixel circuit 232 and the fourth sub-pixel circuit 233. The first sub-pixel 111 includes the first red sub-pixel 41, the first green sub-pixel 42 and the first blue sub-pixel 43. The first sub-pixel circuit 231 is configured to drive the first green sub-pixel 42 to emit light. The third sub-pixel circuit 232 is configured to drive the first red sub-pixel 41 to emit light. The fourth sub-pixel circuit 233 is configured to drive the first blue sub-pixel 43 to emit light. At least one of a first sub-pixel circuit 231, a third sub-pixel circuit 232 or a fourth sub-pixel circuit 233 is configured to drive at least two first sub-pixels 111 electrically connected to the at least one of the first sub-pixel circuit 231, the third sub-pixel circuit 232 or the fourth sub-pixel circuit 233 to emit light.

The solution in which first sub-pixel circuit 231 is configured to drive at least two first green sub-pixels 42 electrically connected to the first sub-pixel circuit 231 to emit light, the solution in which the third sub-pixel circuit 232 is configured to drive at least two first red sub-pixels 41 electrically connected to the third sub-pixel circuit 232 to emit light, the solution in which the fourth sub-pixel circuit 233 is configured to drive at least two first blue sub-pixels 43 electrically connected to the fourth sub-pixel circuit 233 to emit light and the combination of any two or all of the preceding solutions may reduce the number of first sub-pixel circuits 23, thereby improving the transmittance of the first display region 11. In this manner, the sensor disposed at the first display region 11 can receive more external natural light, and the service performance of the sensor is improved. The configuration may be according to actual requirements. This is not limited in this embodiment of the present application.

With continued reference to FIGS. 14 to 16, optionally, at least two first sub-pixels 111 driven by the same first pixel circuit 23 are electrically connected by a transparent conductive layer 35.

As shown in FIGS. 14 to 16, a first pixel circuit 23 is connected to at least two first sub-pixels 111 by the transparent conductive layer 35 to make the first pixel circuit 23 drive the at least two first sub-pixels 111 electrically connected to the first pixel circuit 23 to emit light and reduce the influence of the transparent conductive layer 35 on the transmittance of the first display region 11 at the same time. In this manner, the sensor disposed at the first display region 11 can be ensured to receive more external natural light, and the service performance of the sensor is improved.

With continued reference to FIGS. 14 to 16, optionally, the first pixel circuit 23 also includes the third sub-pixel circuit 232 and the fourth sub-pixel circuit 233. The first sub-pixel 111 includes the first-color light-emitting sub-pixel 47, the second-color light-emitting sub-pixel 48 and the third-color light-emitting sub-pixel 49. At least two first-color light-emitting sub-pixels 47 driven by the same pixel circuit are electrically connected by a first transparent conductive layer 351. At least two second-color light-emitting sub-pixels 48 driven by the same pixel circuit are electrically connected by a second transparent conductive layer 352. At least two third-color light-emitting sub-pixels 49 driven by the same pixel circuit are electrically connected by a third transparent conductive layer 353. The display panel also includes a substrate 341. On the plane where the substrate 341 is located, the vertical projection of the first transparent conductive layer 351 overlaps the vertical projection of the first pixel circuit 23 configured to drive the first-color light-emitting sub-pixels to emit light. Alternatively, on the plane where the substrate 341 is located, the vertical projection of the first transparent conductive layer 351 does not overlap the vertical projection of the first pixel circuit 23. The vertical projection of at least part of the second transparent conductive layer 352 on the plane where the substrate 341 is located overlaps the vertical projections the first pixel circuits configured to drive the first-color light-emitting sub-pixels and/or the first pixel circuit configured to drive the third-color light-emitting sub-pixel to emit light on the plane where the substrate 341 is located. The vertical projection of at least part of the third transparent conductive layer 353 on the plane where the substrate 341 is located overlaps the vertical projections of the first pixel circuit 23 configured to drive the first-color light-emitting sub-pixel 47 and/or of the first pixel circuit 23 configured to drive the second-color light-emitting sub-pixel 48 to emit light on the plane where the substrate 341 is located.

For example, as shown in FIGS. 14 to 16, the first-color light-emitting sub-pixel 47 is the first green sub-pixel 42, the second-color light-emitting sub-pixel 48 is the first red sub-pixel 41, and the third-color light-emitting sub-pixel 49 is the first blue sub-pixel 43. Four first green sub-pixels 42 driven by the same pixel circuit are electrically connected by the first transparent conductive layer 351. Two first red sub-pixels 41 driven by the same pixel circuit are electrically connected by the second transparent conductive layer 352. Two first blue sub-pixels 43 driven by the same pixel circuit are electrically connected by the third transparent conductive layer 353. The vertical projection of the first transparent conductive layer 351 extending in a row direction on the plane where the substrate 341 is located overlaps the vertical projection of the first sub-pixel circuit 231 that drives the first green sub-pixel 42 to emit light on the plane where the substrate 341 is located. The vertical projection of the first transparent conductive layer 351 extending in a column direction on the plane where the substrate 341 is located does not overlap the vertical projection of the first sub-pixel circuit 231 that drives the first green sub-pixel 42 to emit light on the plane where the substrate 341 is located. The vertical projection of the second transparent conductive layer 352 on the plane where the substrate 341 is located overlaps the vertical projections of the first sub-pixel circuit 231 that drives the first green sub-pixel 42 and of the fourth sub-pixel circuit 233 that drives the first blue sub-pixel 43 to emit light on the plane where the substrate 341 is located. The vertical projection of the third transparent conductive layer 353 on the plane where the substrate 341 is located overlaps the vertical projections of the first sub-pixel circuit 231 that drives the first green sub-pixel 42 and of the third sub-pixel circuit 232 that drives the first red sub-pixel 41 to emit light on the plane where the substrate 341 is located.

Through the preceding arrangement, on the basis of ensuring the four first green sub-pixels 42 driven by the same pixel circuit, two first red sub-pixels 41 driven by the same pixel circuit, and two first blue sub-pixels 43 driven by the same pixel circuit, it is also possible to ensure that no short circuit occurs between the first transparent conductive layer 351, the second transparent conductive layer 352 and the third transparent conductive layer 353, thereby implementing the normal display of the first display region 11.

At the same time, in the thickness direction of the display panel, the first transparent conductive layer 351 is configured to overlap only the first sub-pixel circuit 231 that drives the first green sub-pixel 42 to emit light, or the first transparent conductive layer 351 does not overlap the first sub-pixel circuit 231 that drives the first green sub-pixel 42 to emit light, thereby avoiding the formation of the parasitic capacitance between the first transparent conductive layer 351 and the first sub-pixel circuit 231, the third sub-pixel circuit 232 and the fourth sub-pixel circuit 233. In this manner, the influence of the first transparent conductive layer 351 on the first sub-pixel circuit 231, the third sub-pixel circuit 232 and the fourth sub-pixel circuit 233 is reduced, and the influence of the first transparent conductive layer 351 on the brightness of the first green sub-pixel 42, the first red sub-pixel 41 and the first blue sub-pixel 43 is reduced, thereby improving the display effect of the display panel.

With continued reference to FIG. 14, optionally, the extension length of the first transparent conductive layer 351 is less than the extension length of the second transparent conductive layer 352 and the extension length of the third transparent conductive layer 353.

For example, as shown in FIG. 14, the first-color light-emitting sub-pixel 47 is the first green sub-pixel 42, the second-color light-emitting sub-pixel 48 is the first red sub-pixel 41, and the third-color light-emitting sub-pixel 49 is the first blue sub-pixel 43. The extension length of the first transparent conductive layer 351 is configured to be less than the extension length of the second transparent conductive layer 352 and the extension length of the third transparent conductive layer 353 to reduce the extension length of the first transparent conductive layer 351 and reduce the resistance of the first transparent conductive layer 351. In this manner, the signal voltage drop on the first transparent conductive layer 351 is reduced, and the brightness of a first-color light-emitting sub-pixel 47 is ensured. At the same time, since human eyes are most sensitive to green, but insensitive to blue and red, the first-color light-emitting sub-pixel 47 is configured to be the first green sub-pixel 42 to ensure the brightness of the first green sub-pixel 42. In this manner, the difference between the visual effect of the first display region 11 and the visual effect of the second display region 12 is reduced, the phenomenon of uneven display brightness in the visual effect of the first display region 11 and the second display region 12 is alleviated, and the display effect of the display panel is improved.

With continued reference to FIG. 14, optionally, the line width of the first transparent conductive layer 351 is less than the line width of the second transparent conductive layer 352 and the line width of the third transparent conductive layer 353.

As shown in FIG. 14, each of the line width of the second transparent conductive layer 352 and the line width of the third transparent conductive layer 353 is configured to be greater than the line width of the first transparent conductive layer 351 to reduce the resistance of the second transparent conductive layer 352 and the resistance of the third transparent conductive layer 353, thereby reducing the signal voltage drop on the second transparent conductive layer 352 and the signal voltage drop on the third transparent conductive layer 353 and ensuring the brightness of the second-color light-emitting sub-pixel 48 and the brightness of the third-color light-emitting sub-pixel 49. In this manner, the difference between the visual effect of the first display region 11 and the visual effect of the second display region 12 is reduced, the phenomenon of uneven display brightness in the visual effect of the first display region 11 and the second display region 12 is alleviated, and the display effect of the display panel is improved.

The description is given with reference to the preceding embodiment by using only an example in which the first-color light-emitting sub-pixel 47 is the first green sub-pixel 42, the second-color light-emitting sub-pixel 48 is the first red sub-pixel 41, and the third-color light-emitting sub-pixel 49 is the first blue sub-pixel 43. In other embodiments, the emitted colors and the connection arrangement of the first-color light-emitting sub-pixel 47, the second-color light-emitting sub-pixel 48 and the third-color light-emitting sub-pixel 49 may be configured according to actual requirements. This is not limited in this embodiment of the present application.

The pixel arrangement, pixel circuit arrangement, pixel circuit structure and connection relationship shown in FIGS. 7 and 8 are the same as the pixel arrangement, pixel circuit arrangement, pixel circuit structure and connection relationship shown in FIGS. 14 and 15. The difference is in only the size of a pixel opening. Thus, the pixel arrangement, pixel circuit arrangement, pixel circuit structure and connection relationship shown in FIGS. 7 and 8 may be described with reference to FIGS. 14 and 15, and the details are not repeated here.

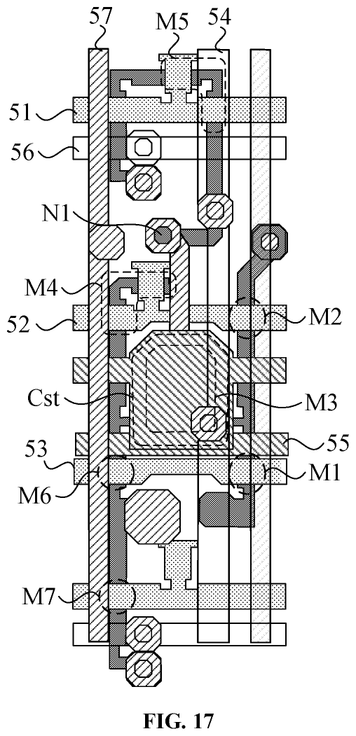

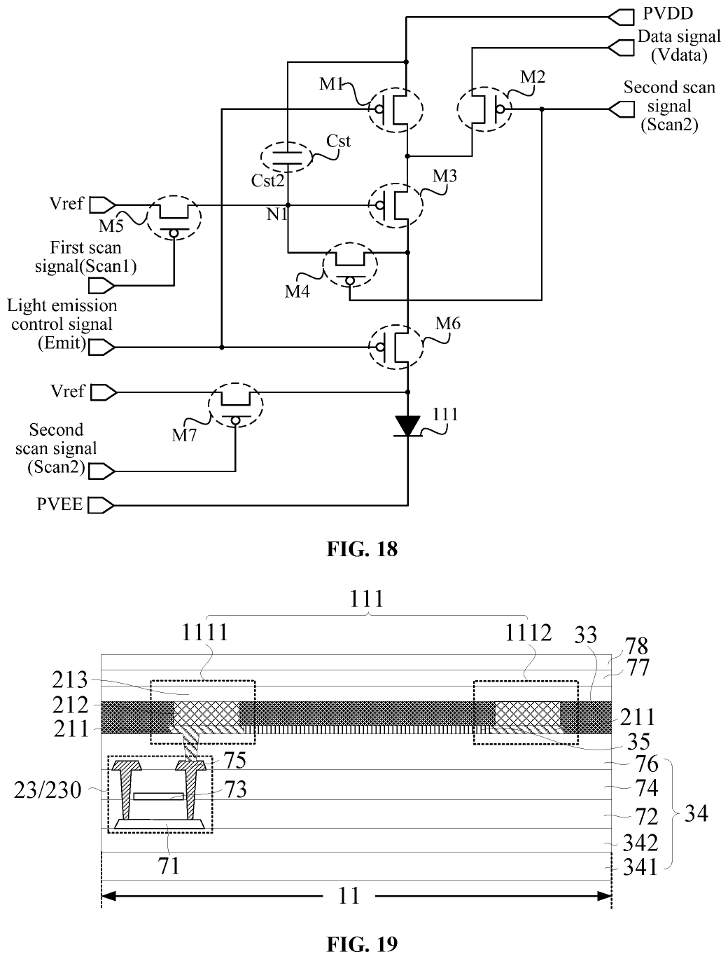

FIG. 17 is a diagram illustrating the structure of a first pixel circuit according to an embodiment of the present application. FIG. 18 is a diagram of circuit elements of a first pixel circuit according to an embodiment of the present application. As shown in FIGS. 15, 17 and 18, optionally, a first pixel circuit 23 includes a drive transistor M3 and a storage capacitor Cst. The gate of the drive transistor M3 is electrically connected to a capacitor plate Cst2 of the storage capacitor Cst at a first node N1. The display panel provided by this embodiment of the present application also includes a substrate 341. The vertical projection of the transparent conductive layer 35 on the plane where the substrate 341 is located does not overlap the vertical projection of the first node N1 on the plane where the substrate 341 is located.

For example, as shown in FIGS. 7, 8, 14, 15, 17 and 18, the first pixel circuit 23 is a 7T1C pixel circuit (seven transistors and one storage capacitor). The display panel may include a first scan line 51, a second scan line 52, a light emission control signal line 53, a first power signal line 54, a second power signal line 55, a reference voltage line 56 and a data line 57. Scan1 is a first scan signal input to the first scan line 51. Scan2 is a second scan signal input to the second scan line 52. Emit is a light emission control signal input to the light emission control signal line 53. Vdata is a data signal input to the data line 57. Vref is a reference voltage signal input to the reference voltage line 56. PVDD is a first power signal input to the first power signal line 54. PVEE is a second power signal, on the second power signal line 55, for forming the current loop of a light-emitting element.

With continued reference to FIGS. 15, 17 and 18, the first pixel circuit 23 may include a first light emission control transistor M1, a data signal write transistor M2, a drive transistor M3, an additional transistor M4, a memory cell reset transistor M5, a second light emission control transistor M6, a light-emitting reset transistor M7 and a storage capacitor Cst. The memory cell reset transistor M5 is configured to provide a reset voltage for the storage capacitor Cst before a display stage. The light-emitting reset transistor M7 is configured to provide an initialization voltage for a first sub-pixel 111 before the display stage. The light emission control signal Emit controls the first light emission control transistor M1 and the second light emission control transistor M6 to be turned on or cut off. The first scan signal Scan′ controls the memory cell reset transistor M5 to be turned on or cut off. The second scan signal Scan2 controls the light-emitting reset transistor M7, the data signal write transistor M2 and the additional transistor M4 to be turned on or cut off.

For example, the driving process in which the first pixel circuit 23 drives the first sub-pixel 111 shown in FIGS. 17 and 18 is below.

In an initialization stage, the first scan signal Scan1 on the first scan line 51 enables the memory cell reset transistor M5 to be turned on, and the potential Vref on the reference voltage line 56 is applied to the second plate Cst2 of the storage capacitor Cst through the memory cell reset transistor M5 to reset the N1 node, that is, the potential of the first node N1 is a reference voltage Vref. At this time, the potential of the gate of the drive transistor M3 is also the reference voltage Vref.

In a data signal voltage write stage, the signal Scan2 on the second scan line 52 enables the data signal write transistor M2 and the additional transistor M4 to be turned on. At this time, the potential of the gate of the drive transistor M3 is the reference voltage Vref and also a low potential, and the drive transistor M3 is also turned on. The data signal Vdata on the data line 57 is applied to the first node N1 through the data signal write transistor M2, the drive transistor M3 and the additional transistor M4. In this manner, a data voltage is written to the storage capacitor Cst.

In the data signal voltage write stage, the signal Scan2 on the second scan line 52 enables the light-emitting reset transistor M7 to be also turned on. The light-emitting reset transistor M7 is configured to write the potential Vref on the reference voltage line 56 to the anode of the first sub-pixel 111 and reset the anode potential of the first sub-pixel 111 to reduce the influence of the anode voltage of the first sub-pixel 111 of a preceding frame on the anode voltage of the first sub-pixel 111 of a succeeding frame and improve display uniformity.

In a light-emitting stage, the light emission control signal Emit on the light emission control signal line 53 enables the first light emission control transistor M5 and the second light emission control transistor M6 to be turned on. In this manner, the drive transistor M3 drives the first sub-pixel 111 to emit light.

In the preceding process in which the first pixel circuit 23 drives the first sub-pixel 111 to work, the drive transistor M3 provides the drive current for the first sub-pixel 111 according to the gate potential of the drive transistor M3 to drive the first sub-pixel 111 to emit light. In this embodiment, the vertical projection of the transparent conductive layer 35 on the plane where the substrate 341 is located is configured not to overlap the vertical projection of the first node N1 on the plane where the substrate 341 is located to prevent the transparent conductive layer 35 from forming parasitic capacitance at the position of the first node N1 and affecting the gate voltage of the drive transistor M3, thereby ensuring the brightness of the first sub-pixel 111. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

FIG. 19 is a section view illustrating a partial structure of another display panel according to an embodiment of the present application. As shown in FIG. 19, optionally, at least two first sub-pixels 111 driven by the same first pixel circuit 23 include a first sub-pixel A 1111 and a first sub-pixel B 1112. The first anode 211 of the first sub-pixel A 1111 is electrically connected to the first pixel circuit 23 through a via. The first anode 211 of the first sub-pixel A 1111 is electrically connected to the first anode 211 of the first sub-pixel B 1112 by the transparent conductive layer 35.

As shown in FIG. 19, with the configuration in which the first anode 211 of the first sub-pixel A 1111 is electrically connected to the first pixel circuit 23 through the via, and the first anode 211 of the first sub-pixel A 1111 is electrically connected to the first anode 211 of the first sub-pixel B 1112 by the transparent conductive layer 35 to make the first pixel circuit 23 simultaneously drive the first sub-pixel A 1111 and the first sub-pixel B 1112 to emit light.

The at least two first sub-pixels 111 driven by one first pixel circuit 23 may be first sub-pixels 111 of any color to reduce the number of first sub-pixel circuits 23, thereby improving the transmittance of the first display region 11. In this manner, the sensor disposed at the first display region 11 can receive more external natural light, and the service performance of the sensor is improved.

With continued reference to FIGS. 14 and 19, optionally, a plurality of first pixel circuits 23 are arranged in an array and include a plurality of first pixel circuit groups 230. A first pixel circuit group 230 includes at least two adjacent first pixel circuit columns. The display panel also includes a substrate 341. The vertical projection of the first sub-pixel A 1111 on the plane where the substrate 341 is located overlaps the vertical projection of the first pixel circuit group 230 on the plane where the substrate 341 is located. On the plane where the substrate 341 is located, the vertical projection of at least part of the first sub-pixel B 1112 overlaps the vertical projection of the gap between two adjacent first pixel circuit groups 230.

For example, as shown in FIGS. 14 and 19, the vertical projection, on the plane where the substrate 341 is located, of the first sub-pixel A 1111 is configured to overlap the vertical projection of the first pixel circuit group 230 on the plane where the substrate 341 is located to make the first anode 211 in the first sub-pixel A 1111 electrically connected with the first pixel circuit 23 in the first pixel circuit group 230 through the via. On the plane where the substrate 341 is located, the vertical projection of at least part of the first sub-pixel B 1112 is configured to overlap the vertical projection of the gap between two adjacent first pixel circuit groups 230. In this manner, the first sub-pixel A 1111 and the first sub-pixel B 1112 are uniformly distributed, and the display uniformity of the first display region 11 is improved.

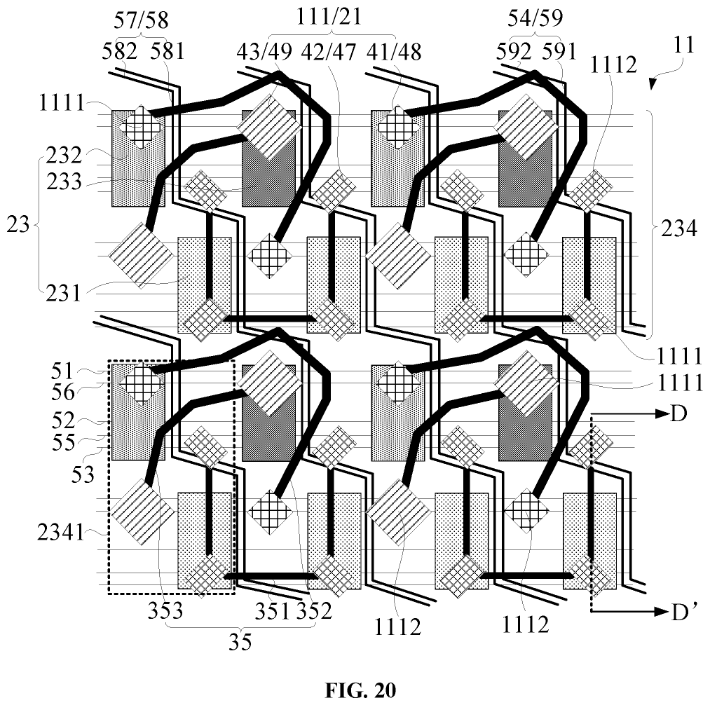

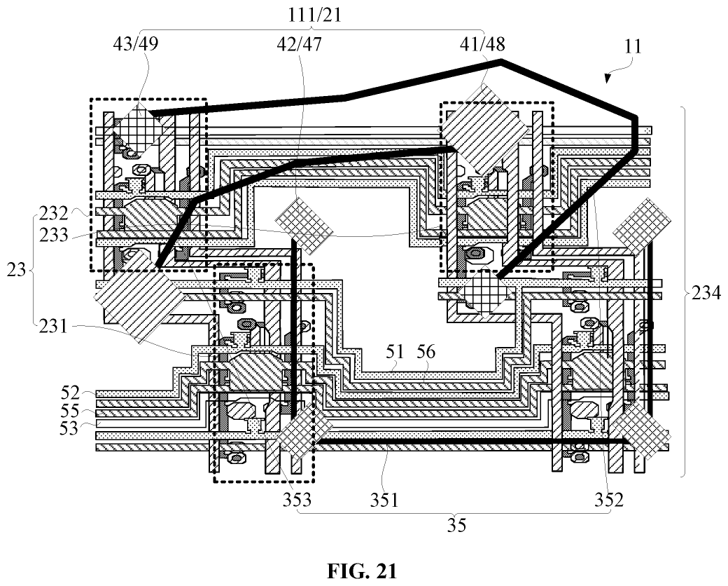

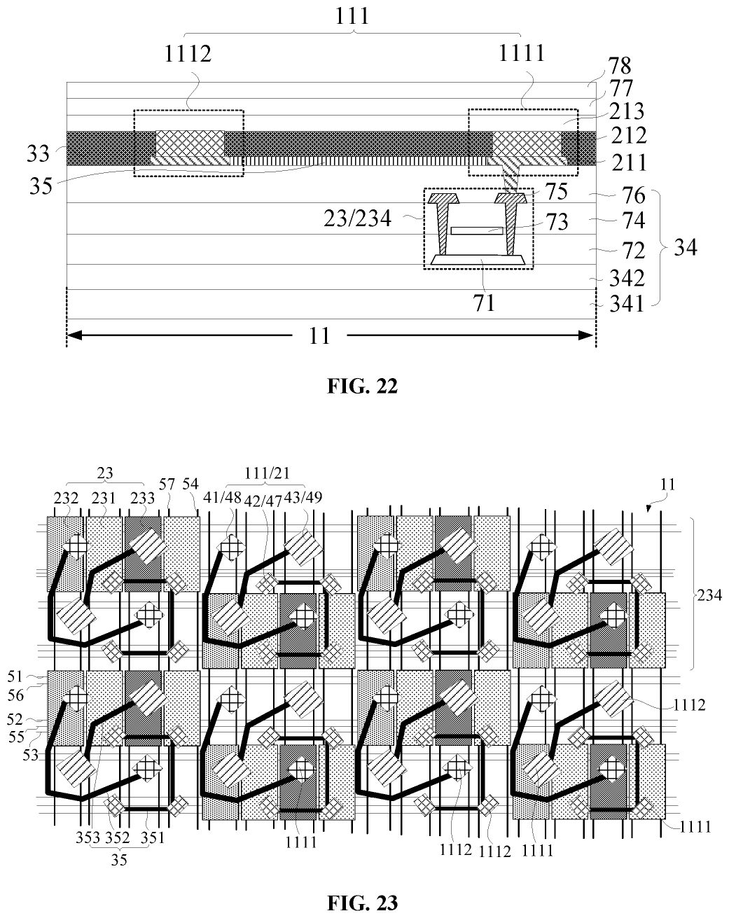

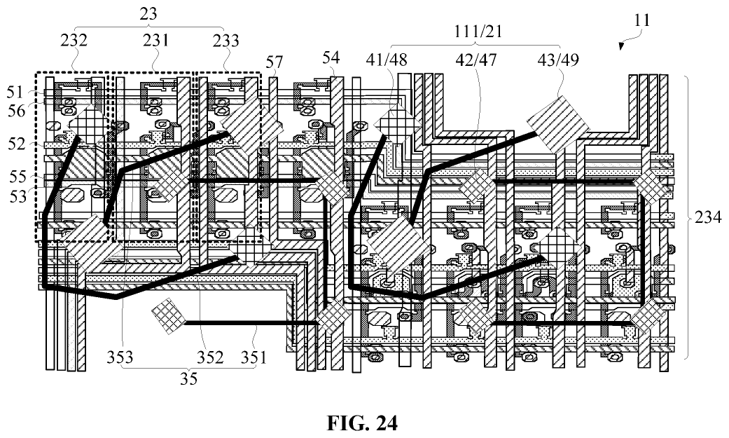

FIG. 20 is a diagram illustrating a partial structure of another display panel according to an embodiment of the present application. FIG. 21 is an enlarged partial view of FIG. 20. FIG. 22 is a section view taken along direction D-D′ of FIG. 20. FIG. 23 is a diagram illustrating a partial structure of another display panel according to an embodiment of the present application. FIG. 24 is an enlarged partial view of FIG. 23. As shown in FIGS. 20 to 24, optionally, a plurality of first pixel circuits 23 are arranged in an array and include a plurality of second pixel circuit groups 234. A second pixel circuit group 234 includes at least two adjacent first pixel circuit rows. Two adjacent first pixel circuit rows in the same second pixel circuit group 234 are staggered in the row direction. The row direction is the extension direction of the first pixel circuit rows. The display panel also includes a substrate 341. The vertical projection of the first sub-pixel A 1111 on the plane where the substrate 341 is located overlaps the vertical projection of the second pixel circuit group 234 on the plane where the substrate 341 is located. On the plane where the substrate 341 is located, the vertical projection of at least part of the first sub-pixel B 1112 overlaps the vertical projection of the gap between two adjacent first pixel circuits 23 in a first pixel circuit row of the same second pixel circuit group 234.

For example, as shown in FIGS. 20 to 24, with the configuration in which the second pixel circuit group 234 includes at least two adjacent first pixel circuit rows, and the two adjacent first pixel circuit rows in the same second pixel circuit group 234 are staggered in the row direction, the distribution of the first pixel circuits 23 is more uniform, and a diffraction phenomenon caused by the gap between adjacent first pixel circuits 23 is alleviated. In this manner, the influence of the diffraction phenomenon on the sensor disposed in the first display region 11 is reduced, and the service performance of the sensor under the screen is improved.

With continued reference to FIGS. 20 to 24, the vertical projection of the first sub-pixel A 1111 on the plane where the substrate 341 is located is configured to overlap the vertical projection of the second pixel circuit group 234 on the plane where the substrate 341 is located to make the first anode 211 in the first sub-pixel A 1111 electrically connected with the first pixel circuit 23 in the first pixel circuit group 230 through the via. On the plane where the substrate 341, the vertical projection of at least part of the first sub-pixel B 1112 is located is configured to overlap the vertical projection of the gap between two adjacent first pixel circuits 23 in the first pixel circuit row of the same second pixel circuit group 234. In this manner, the first sub-pixel A 1111 and the first sub-pixel B 1112 are uniformly distributed, and the display uniformity of the first display region 11 is improved.

Two adjacent first pixel circuit rows in the same second pixel circuit group 234 are staggered in the row direction and are not limited to the arrangement shown in FIGS. 20 and 23. The arrangement of the first pixel circuits 23 may be configured according to actual requirements. This is not limited in this embodiment of the present application.

With continued reference to FIG. 20, optionally, a plurality of second pixel circuit groups 234 include N second pixel circuit groups 234. N denotes a positive integer. Each second pixel circuit group 234 includes M sub-pixel circuit groups 2341. The mth sub-pixel circuit group 2341 includes the mth first pixel circuit 23 in the first pixel circuit row in the same second pixel circuit group 234 and the mth first pixel circuit 23 in the second first pixel circuit row in the same second pixel circuit group 234. M denotes a positive integer, and 1≤m≤M. The first display region 11 also includes M first data signal lines 58. The mth first data signal line 58 is configured to provide data signals Vdata for two first pixel circuits 23 in the (m+n−1)th sub-pixel circuit group 2341 in the nth second pixel circuit group of the second pixel circuit group 234, and 1≤n≤N.

For example, as shown in FIG. 20, when m=1 and n=1, the first data signal line 58 is configured to provide the data signal Vdata for two first pixel circuits 23 in the first sub-pixel circuit group 2341 in the first second pixel circuit group 234. When m=2 and n=1, the second first data signal line 58 is configured to provide the data signal Vdata for two first pixel circuits 23 in the second sub-pixel circuit group 2341 in the first second pixel circuit group 234. The rest are done in the same manner. The mth first data signal line 58 is configured to provide the data signal Vdata for two first pixel circuits 23 in the mth sub-pixel circuit group 2341 in the first second pixel circuit group 234 to make the first data signal line 58 provide the data signal Vdata for the first second pixel circuit group 234. At the same time, when m=1 and n=2, the first data signal line 58 is configured to provide the data signal Vdata for two first pixel circuits 23 in the second sub-pixel circuit group 2341 in the second group of the second pixel circuit groups 234. When m=1 and n=3, the first data signal line 58 is configured to provide the data signal Vdata for two first pixel circuits 23 in the third sub-pixel circuit group 2341 in the third second pixel circuit group 234. The rest are done in the same manner. The first first data signal line 58 is configured to provide the data signal Vdata for two first pixel circuits 23 in the nth sub-pixel circuit group 2341 in the nth second pixel circuit group 234. In this embodiment, the mth first data signal line 58 is configured to provide the data signal Vdata for two first pixel circuits 23 in the (m+n−1)th sub-pixel circuit group 2341 in the nth second pixel circuit group 234 to make a first data signal line 58 extend in an oblique direction. Compared with the disposition of one first data signal line 58 in each first pixel circuit column, the number of first data signal lines 58 is reduced by half by the arrangement of the first data signal lines 58, thereby reducing the reflective area of the first data signal lines 58 and improving the transmittance of the first display region 11. In this manner, the sensor disposed at the first display region 11 can receive more external natural light, and the service performance of the sensor is improved.

With continued reference to FIG. 20, optionally, a first data signal line 58 includes a plurality of first line segments 581 and a plurality of second line segments 582 alternately connected. The extension direction of the first line segment 581 is parallel to the extension direction of the first pixel circuit column. The extension direction of the second line segment 582 intersects the extension direction of the first pixel circuit column. The extension length of the first line segment 581 is greater than the extension length of the second line segment 582.

For example, as shown in FIG. 20, the extension length of the first line segment 581 is configured to be greater than the extension length of the second line segment 582 to make a second line segment 582 connected to an adjacent first pixel circuit column short. In this manner, compared with the disposition of one first data signal line 58 in each first pixel circuit column, the total length of the first data signal lines 58 is reduced, thereby reducing the reflective area of the first data signal lines 58 and improving the transmittance of the first display region 11. Moreover, the sensor disposed at the first display region 11 can receive more external natural light, and the service performance of the sensor is improved.

With continued reference to FIG. 20, optionally, a plurality of second pixel circuit groups 234 include N second pixel circuit groups 234. N denotes a positive integer. Each second pixel circuit group 234 includes M sub-pixel circuit groups 2341. The mth sub-pixel circuit group 2341 includes the mth first pixel circuit 23 in the first pixel circuit row in the same second pixel circuit group 234 and the mth first pixel circuit 23 in the second first pixel circuit row in the same second pixel circuit group 234. M denotes a positive integer, and 1≤m≤M. The first display region 11 also includes M first voltage signal lines 59. The mth first voltage signal line 59 is configured to provide voltage signals for two first pixel circuits 23 in the (m+n−1)th sub-pixel circuit group 2341 in the nth second pixel circuit group 234, and 1≤n≤N.

For example, as shown in FIG. 20, when m=1 and n=1, the first voltage signal line 59 is configured to provide the voltage signal for two first pixel circuits 23 in the first sub-pixel circuit group 2341 in the first second pixel circuit group 234. When m=2 and n=1, the second first voltage signal line 59 is configured to provide the voltage signal for two first pixel circuits 23 in the second sub-pixel circuit group 2341 in the first second pixel circuit group 234. The rest are done in the same manner. The mth first voltage signal line 59 is configured to provide the voltage signal for two first pixel circuits 23 in the mth sub-pixel circuit group 2341 in the first second pixel circuit group 234 to make the first data voltage line 59 provide the data voltage for the first second pixel circuit group 234. At the same time, when m=1 and n=2, the first voltage signal line 59 is configured to provide the voltage signal for two first pixel circuits 23 in the second sub-pixel circuit group 2341 in the second pixel circuit group 234. When m=1 and n=3, the first voltage signal line 59 is configured to provide the voltage signal for two first pixel circuits 23 in the third sub-pixel circuit group 2341 in the third second pixel circuit group 234. The rest are done in the same manner. The first voltage signal line 59 is configured to provide the voltage signal for two first pixel circuits 23 in the nth sub-pixel circuit group 2341 in the nth second pixel circuit group 234. In this embodiment, the mth first voltage signal line 59 is configured to provide the voltage signal for two first pixel circuits 23 in the (m+n−1)th sub-pixel circuit group 2341 in the nth second pixel circuit group 234 to make a first voltage signal line 59 extend in an oblique direction. Compared with the disposition of one first voltage signal line 59 in each first pixel circuit column, the number of first voltage signal lines 59 is reduced by half by the arrangement of the first voltage signal lines 59, thereby reducing the reflective area of the first voltage signal lines 59 and improving the transmittance of the first display region 11. In this manner, the sensor disposed at the first display region 11 can receive more external natural light, and the service performance of the sensor is improved.

With continued reference to FIG. 20, optionally, the first voltage signal line 59 may be the first power signal line 54, and the voltage signal provided is the first power signal PVDD. In other embodiments, the first voltage signal line 59 may also be a signal line transmitting another voltage signal and may be configured according to actual requirements. This is not limited in this embodiment of the present application.

With continued reference to FIG. 20, optionally, a first voltage signal line 59 includes a plurality of third line segments 591 and a plurality of fourth line segments 592 alternately connected. The extension direction of the third line segment 591 is parallel to the extension direction of the first pixel circuit column. The extension direction of the fourth line segment 592 intersects the extension direction of the first pixel circuit column. The extension length of the third line segment 591 is greater than the extension length of the fourth line segment 592.

For example, as shown in FIG. 20, the extension length of the third line segment 591 is configured to be greater than the extension length of the fourth line segment 592 to make a fourth line segment 592 connected to an adjacent first pixel circuit column short. In this manner, compared with the disposition of one first voltage signal line 59 in each first pixel circuit column, the total length of the first voltage signal lines 59 is reduced, thereby reducing the reflective area of the first voltage signal lines 59 and improving the transmittance of the first display region 11. Moreover, the sensor disposed at the first display region 11 can receive more external natural light, and the service performance of the sensor is improved.

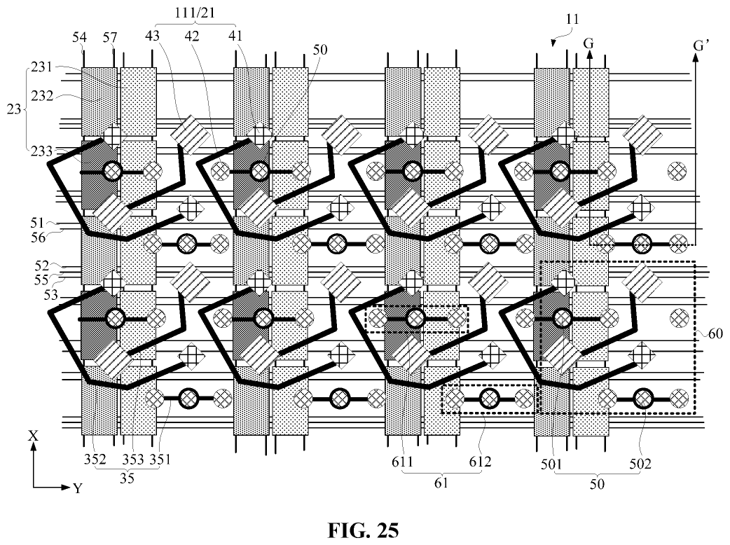

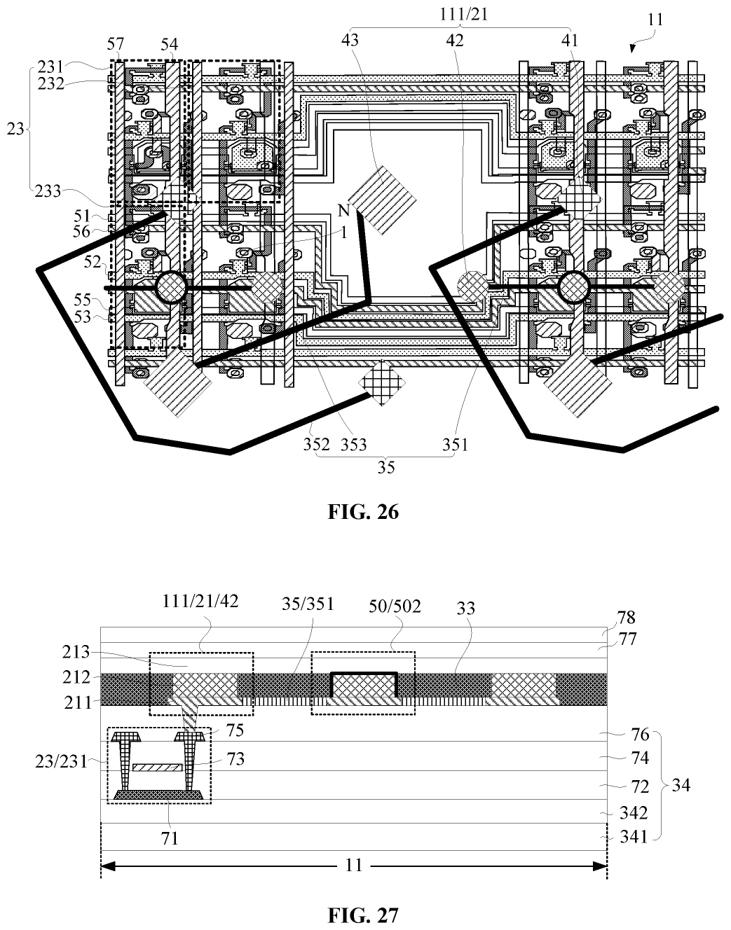

FIG. 25 is a diagram illustrating a partial structure of another display panel according to an embodiment of the present application. FIG. 26 is an enlarged partial view of FIG. 25. FIG. 27 is a section view taken along direction G-G′ of FIG. 25. As shown in FIGS. 25 to 27, optionally, the first display region 11 also includes a plurality of first pixel circuits 23. The first pixel circuit 23 is configured to drive the first sub-pixel 111 to emit light. The first pixel circuit 23 includes the first sub-pixel circuit 231, the third sub-pixel circuit 232 and the fourth sub-pixel circuit 233. The first sub-pixel 111 includes the first red sub-pixel 41, the first green sub-pixel 42 and the first blue sub-pixel 43. The first sub-pixel circuit 231 is configured to drive the first green sub-pixel 42 to emit light. The third sub-pixel circuit 232 is configured to drive the first red sub-pixel 41 to emit light. The fourth sub-pixel circuit 233 is configured to drive the first blue sub-pixel 43 to emit light. At least one of a first sub-pixel circuit 231, a third sub-pixel circuit 232 or a fourth sub-pixel circuit 233 is configured to drive at least two first sub-pixels 111 electrically connected to the at least one of the first sub-pixel circuit 231, the third sub-pixel circuit 232 or the fourth sub-pixel circuit 233 to emit light. The first display region 11 also includes brightness adjustment sub-pixels 50. A brightness adjustment sub-pixel is electrically connected to at least two first sub-pixels 111 of the same color. A first sub-pixel circuit 231 is configured to drive at least two first sub-pixels 111 electrically connected to the first sub-pixel circuit 231 and a brightness adjustment sub-pixel 50 electrically connected to the first sub-pixel circuit 231. Alternatively, a third sub-pixel circuit 232 is configured to drive at least two first sub-pixels 111 electrically connected to the third sub-pixel circuit 232 and a brightness adjustment sub-pixel 50 electrically connected to the third sub-pixel circuit 232. Alternatively, a fourth sub-pixel circuit 233 is configured to drive at least two first sub-pixels 111 electrically connected to the fourth sub-pixel circuit 233 and a brightness adjustment sub-pixel 50 electrically connected to the fourth sub-pixel circuit 233.

As shown in FIGS. 25 to 27, the solution in which first sub-pixel circuit 231 is configured to drive at least two first green sub-pixels 42 electrically connected to the first sub-pixel circuit 231 to emit light, the solution in which the third sub-pixel circuit 232 is configured to drive at least two first red sub-pixels 41 electrically connected to the third sub-pixel circuit 232 to emit light, the solution in which the fourth sub-pixel circuit 233 is configured to drive at least two first blue sub-pixels 43 electrically connected to the fourth sub-pixel circuit 233 to emit light and the combination of any two or all of the preceding solutions may reduce the number of first sub-pixel circuits 23, thereby improving the transmittance of the first display region 11. In this manner, the sensor disposed at the first display region 11 can receive more external natural light, and the service performance of the sensor is improved. The configuration may be according to actual requirements. This is not limited in this embodiment of the present application.

With continued reference to FIGS. 25 to 27, in this embodiment, the brightness adjustment sub-pixel 50 is added in the first display region 11, and the brightness adjustment sub-pixel 50 and at least two first sub-pixels 111 of the same color are configured to be driven by the same first pixel circuit 23. In this manner, the pixel distribution density of the first display region 11 is increased while a first pixel circuit 23 is not added, thereby increasing the brightness of the first display region 11. Moreover, the difference between the visual effect of the first display region 11 and the visual effect of the second display region 12 is reduced, the phenomenon of uneven display brightness in the visual effect of the first display region 11 and the second display region 12 is alleviated, and the display effect of the display panel is improved.

With continued reference to FIGS. 25 to 27, optionally, the first display region 11 includes a plurality of repeated sub-pixel units 60. The brightness adjustment sub-pixel 50 is located in the repeated sub-pixel unit 60.

For example, as shown in FIGS. 25 to 27, for example, the repeated sub-pixel unit 60 includes two first red sub-pixel 41, two first blue sub-pixel 43 and four first green sub-pixels 42. With the configuration in which the brightness adjustment sub-pixels 50 are located in the repeated sub-pixel units 60, added brightness adjustment sub-pixels 50 are uniformly distributed along with the repeated sub-pixel units 60, and the display uniformity of the first display region 11 is improved.

With continued reference to FIGS. 25 to 27, optionally, the display panel provided by this embodiment of the present application also includes a substrate 341. The brightness adjustment sub-pixel 50 includes the first brightness adjustment sub-pixel 501 and the second brightness adjustment sub-pixel 502. The vertical projection of a first brightness adjustment sub-pixel 501 on the plane where the substrate 341 is located overlaps the vertical projection of a first pixel circuit 23 on the plane where the substrate 341 is located. On the plane where the substrate 341 is located, the vertical projection of a second brightness adjustment sub-pixel 502 overlaps the vertical projection of the gap between two adjacent first pixel circuits 23.

For example, as shown in FIGS. 25 to 27, with the configuration in which the vertical projection of the first brightness adjustment sub-pixel 501 on the plane where the substrate 341 is located overlaps the vertical projection of the first pixel circuit 23 on the plane where the substrate 341 is located; and on the plane where the substrate 341 is located, the vertical projection of the second brightness adjustment sub-pixel 502 overlaps the vertical projection of the gap between the two adjacent first pixel circuits 23, the first brightness adjustment sub-pixels 501 and the second brightness adjustment sub-pixels 502 may be more uniformly distributed, and the display uniformity of the first display region 11 is improved.

Additionally, on the plane where the substrate 341 is located, the vertical projection of the second brightness adjustment sub-pixel 502 is configured to overlap the vertical projection of the gap between the two adjacent first pixel circuits 23 to avoid the formation of the parasitic capacitance between the second brightness adjustment sub-pixel 502 and a first pixel circuit 23. In this manner, the influence of the second brightness adjustment sub-pixel 502 on the first pixel circuit 23 is reduced, and the display effect of the display panel is improved.

With continued reference to FIG. 25, optionally, in a first direction X, the first brightness adjustment sub-pixel 501 is located between two sub-pixels that are in the same repeated sub-pixel unit 60 and that have a different emitted color from the emitted color of the first brightness adjustment sub-pixel 501. In the first direction X, the second brightness adjustment sub-pixel 502 is located between two sub-pixels that are between two adjacent repeated sub-pixel units 60 and that have a different emitted color from the emitted color of the second brightness adjustment sub-pixel 502. The display panel also includes data lines 57. The first direction is parallel to the extension direction of the data lines 57.

For example, as shown in FIG. 25, the first brightness adjustment sub-pixels 501 and the second brightness adjustment sub-pixels 502 emit green light. In the first direction X, the first brightness adjustment sub-pixel 501 is located between a first red sub-pixel 41 and a first blue sub-pixel 43 in the same repeated sub-pixel unit 60, and the second brightness adjustment sub-pixel 502 is located between a first red sub-pixel 41 and a first blue sub-pixel 43 in two adjacent repeated sub-pixel units 60. In this embodiment, each of the first brightness adjustment sub-pixel 501 and the second brightness adjustment sub-pixel 502 is configured to be located between two sub-pixels whose emitted colors are different from the emitted color of the first brightness adjustment sub-pixel 501 and the emitted color of the second brightness adjustment sub-pixel 502. In this manner, the two sub-pixels whose emitted colors are different from the emitted color of the first brightness adjustment sub-pixel 501 and the emitted color of the second brightness adjustment sub-pixel 502 are arranged uniformly, and the display effect of the display panel is improved.

With continued reference to FIGS. 25 to 27, optionally, a brightness adjustment sub-pixel 50 and at least two first sub-pixels 111 driven by the same first pixel circuit 23 are sequentially arranged in a second direction Y. In the second direction Y, the brightness adjustment sub-pixel 50 is located between the first sub-pixels 111. The display panel also includes data lines 57. The second direction Y intersects the extension direction of the data lines 57.

For example, as shown in FIGS. 25 to 27, with the configuration in which the brightness adjustment sub-pixel 50 and the at least two first sub-pixels 111 driven by the same first pixel circuit 23 are sequentially arranged in the second direction Y, and the brightness adjustment sub-pixel 50 is located between the first sub-pixels 111, added brightness adjustment sub-pixels 50 are more uniformly distributed, and the display uniformity of the first display region 11 is improved.

With continued reference to FIG. 25, optionally, the brightness adjustment sub-pixels 50 include first brightness adjustment sub-pixels 501 and second brightness adjustment sub-pixels 502. The brightness adjustment sub-pixel 50 and the at least two first sub-pixels 111 driven by the same first pixel circuit 23 form one sub-pixel unit group 61. The sub-pixel unit group 61 includes the first sub-pixel unit group 611 and the second sub-pixel unit group 612. The first sub-pixel unit group 611 includes the first brightness adjustment sub-pixel 501. The second sub-pixel unit group 612 includes the second brightness adjustment sub-pixel 502. The display panel also includes data lines 57. A first sub-pixel unit group 611 and a second sub-pixel unit group 612 that are adjacent in the second direction Y share the same data line 57. The second direction Y intersects the extension direction of the data lines 57.

For example, as shown in FIG. 25, compared with the disposition of one first data signal line 58 in each first pixel circuit column, the first sub-pixel unit group 611 and the second sub-pixel unit group 612 that are adjacent in the second direction Y are configured to share the same data line 57 to reduce the number of the data lines 57, thereby reducing the reflective area of data lines 57 and improving the transmittance of the first display region 11. In this manner, the sensor disposed at the first display region 11 can receive more external natural light, and the service performance of the sensor is improved.

With continued reference to FIGS. 25 to 27, optionally, the brightness adjustment sub-pixels 50 include green sub-pixels. The first sub-pixel circuit 231 is configured to drive at least two first green sub-pixels 42 and the brightness adjustment sub-pixel 50 electrically connected to the first sub-pixel circuit 231 to emit light.

As shown in FIGS. 25 to 27, under the same brightness, human eyes are most sensitive to green, but insensitive to blue and red. For this reason, the brightness adjustment sub-pixels 50 include green sub-pixels. The first sub-pixel circuit 231 is configured to drive the at least two first green sub-pixels 42 and the brightness adjustment sub-pixel 50 electrically connected to the first sub-pixel circuit 231 to emit light to increase the green sub-pixel and ensure the green brightness in the first display region 11. In this manner, the visual effect difference between the first display region 11 and the second display region 12 is reduced, the phenomenon of uneven display brightness in the visual effect of the first display region 11 and the second display region 12 is alleviated, and the display effect of the display panel is improved.

With continued reference to FIGS. 25 to 27, optionally, a brightness adjustment sub-pixel 50 is electrically connected to at least two first sub-pixels 111 of the same color by the transparent conductive layer 35.

For example, as shown in FIGS. 25 to 27, the brightness adjustment sub-pixel 50 is connected to the at least two first sub-pixels 111 of the same color by the transparent conductive layer 35 to make a first pixel circuit 23 drive the brightness adjustment sub-pixel 50 connected to the first pixel circuit 23 and the at least two first sub-pixels 111 of the same color and reduce the influence of the transparent conductive layer 35 on the transmittance of the first display region 11 at the same time. In this manner, the sensor disposed at the first display region 11 can be ensured to receive more external natural light, and the service performance of the sensor is improved.

The description is given with reference to the embodiment illustrated in FIGS. 25 to 27 by using only an example in which a brightness adjustment sub-pixel 50 is electrically connected to at least two first green sub-pixels 42 (that is, the brightness adjustment sub-pixel 50 emits green light). In other embodiments, the brightness adjustment sub-pixel 50 may also be electrically connected to at least two first red sub-pixels 41 (that is, the brightness adjustment sub-pixel 50 emits red light). Alternatively, the brightness adjustment sub-pixel 50 may also be electrically connected to at least two first blue sub-pixels 43 (that is, the brightness adjustment sub-pixel 50 emits blue light). Moreover, the combination of any two or all of the preceding solutions is applied. The configuration may be according to actual requirements.

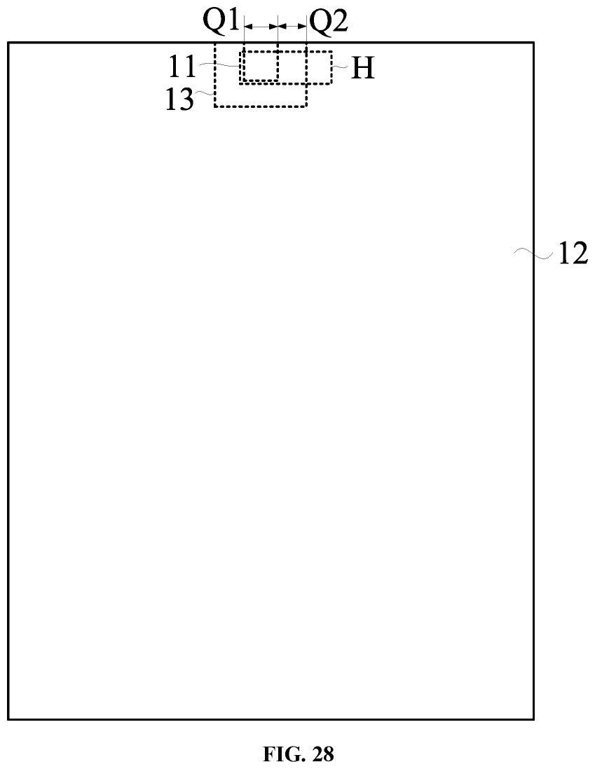

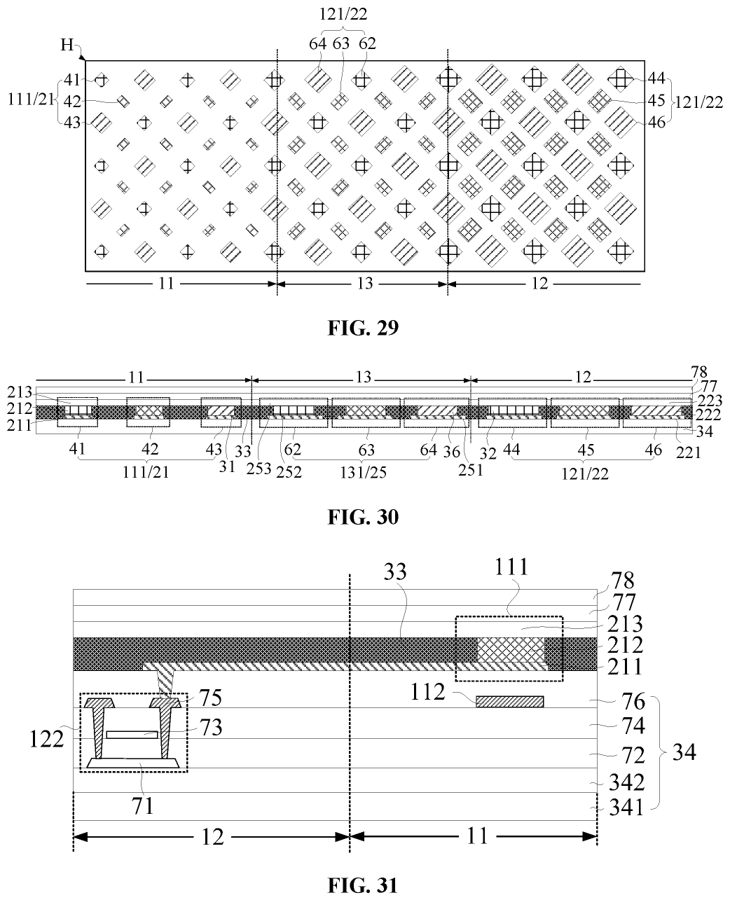

FIG. 28 is a diagram illustrating the structure of another display panel according to an embodiment of the present application. FIG. 29 is an enlarged view illustrating the structure of part H of FIG. 28. FIG. 30 is a section view illustrating a partial structure of another display panel according to an embodiment of the present application. As shown in FIGS. 28 to 30, optionally, the display panel according to this embodiment of the present application also includes a third display region 13 located between the first display region 11 and the second display region 12. The third display region 13 includes a plurality of third sub-pixels 131. The third sub-pixel 131 includes the first-type third sub-pixel 25. The emitted color of the first-type third sub-pixel 23 are is same as the emitted color of the first-type first sub-pixel 21 and the emitted color of the first-type second sub-pixel 22. A first-type third sub-pixel 25 includes a third anode 251. The area of the third anode 251 is greater than the area of the first anode 211 and less than the area of the second anode 221.

With continued reference to FIGS. 28 to 30, for example, the third display region 13 includes multiple third sub-pixels 131 arranged in an array. The first-type third sub-pixel 25 in a third sub-pixel 131 includes a third anode 251, a third organic light-emitting layer 252 and a third cathode 253 sequentially stacked. An electron and a hole are injected from the third cathode 253 and the third anode 251 into the third organic light-emitting layer 252 separately, and then an exciton is formed in the third organic light-emitting layer 252 to excite a light-emitting molecule. In this manner, the third light-emitting layer 252 may emit visible light.

With continued reference to FIGS. 28 to 30, in this embodiment, the area of the third anode 251 in the first-type third sub-pixel 25 is configured to be greater than the area of the first anode 211 in the first-type first sub-pixel 21 and less than the area of the second anode 221 in the first-type second sub-pixel 22 to make the spacing between the third anodes 251 of adjacent first-type third sub-pixels 25 in the third display region 13 is between the spacing between the first anodes 211 of adjacent first-type first sub-pixels 21 in the first display region 11 and the spacing between the second anodes 221 of adjacent first-type second sub-pixels 22 in the second display region 12. In this manner, there is a transition region between the first display region 11 and the second display region 12, the phenomenon of uneven display brightness in the visual effect between the first display region 11 and the second display region 12 is alleviated, and the display effect of the display panel is improved.

With continued reference to FIGS. 28 to 30, for example, third sub-pixel 131 located in the third display region 13 includes the third red sub-pixel 62, the third green sub-pixels 63 and the third blue sub-pixels 64 to implement the color display of the third display region 13.

With continued reference to FIGS. 28 to 30, optionally, the first-type third sub-pixel 25 is configured to include the third red sub-pixel 62, the third green sub-pixel 63 and the third blue sub-pixel 64. That is, the area of the third anode 251 in a third red sub-pixel 62 is configured to be greater than the area of the first anode 211 in a first red sub-pixel 41 and less than the area of the second anode 221 in a second red sub-pixel 44; the area of the third anode 251 in a third green sub-pixel 63 is configured to be greater than the area of the first anode 211 in a first green sub-pixel 42 and less than the area of the second anode 221 in a second green sub-pixel 45; and the area of the third anode 251 in a third blue sub-pixel 64 is configured to be greater than the area of the first anode 211 in a first blue sub-pixel 43 and less than the area of the second anode 221 in a second blue sub-pixel 46. In this manner, the phenomenon of uneven display brightness in the visual effect between the first display region 11 and the second display region 12 is alleviated, and the display effect of the display panel is improved.

The description is given with reference to FIGS. 28 to 30 by using only an example in which the first-type third sub-pixel 25 includes the third red sub-pixel 62, the third green sub-pixel 63 and the third blue sub-pixel 64. In other embodiments, third sub-pixel 25 may include only the third red sub-pixel 62. Alternatively, the third sub-pixel 25 may include only the third green sub-pixel 63. Alternatively, the third sub-pixel 25 may include only the third blue sub-pixel 64.

Alternatively, the combination of any two or all of the preceding solutions is applied. The configuration may be according to actual requirements.

With continued reference to FIGS. 28 to 30, optionally, the third display region 13 includes a plurality of third sub-pixels 131. The pixel distribution density of the first sub-pixels 111, the pixel distribution density of the second sub-pixels 121 and the pixel distribution density of the third sub-pixels 131 are the same.

As shown in FIGS. 28 to 30, the pixel distribution density of the first sub-pixels 111, the pixel distribution density of the second sub-pixels 121 and the pixel distribution density of the third sub-pixels 131 are configured to be the same to ensure that the number of first sub-pixels 111 per unit area of the first display region 11, the number of second sub-pixels 121 per unit area of the second display region 12 and the number of third sub-pixels 131 per unit area of the third display region 13 are equal. In this manner, the brightness difference between the first display region 11, the second display region 12 and the third display region 13 is reduced, the phenomenon of uneven display brightness in the visual effect of the first display region 11, the second display region 12 and the third display region 13 is alleviated, and the display effect of the display panel is improved.

The position, shape and size of the first display region 11 and the third display region 13 may be configured according to actual requirements. For example, as shown in FIG. 28, the width Q1 of the first display region 11 is equal to the width Q2 of the third display region 13. This is not limited in this embodiment of the present application.

With continued reference to FIGS. 28 to 30, optionally, the first-type first sub-pixel 21 also includes a first pixel opening 31. The first-type second sub-pixel 22 also includes a second pixel opening 32. The first-type third sub-pixel 25 also includes a third pixel opening 36. The area of the third pixel opening 36 is greater than the area of the first pixel opening 31 and less than the area of the second pixel opening 32.

As shown in FIG. 30, the display panel also includes a pixel defining layer 33. Each of the first pixel opening 31, the second pixel opening 32 and the third pixel opening 36 is a pixel opening disposed on the pixel defining layer 33. The first pixel opening 31 is located in the first display region 11. The first organic light-emitting layer 212 is located in the first pixel opening 31. The second pixel opening 32 is located in the second display region 12. The second organic light-emitting layer 222 is located in the second pixel opening 32. The third pixel opening 36 is located in the third display region 13. The third organic light-emitting layer 252 is located in the third pixel opening 36. For this reason, the region where the first pixel opening 31 is located is the region where the first organic light-emitting layer 212 is located; the region where the second pixel opening 32 is located is the region where the second organic light-emitting layer 222 is located; and the region where the third pixel opening 36 is located is the region where the third organic light-emitting layer 252 is located.

In this embodiment, the area of the third pixel opening 36 is configured to be greater than the area of the first pixel opening 31 and less than the area of the second pixel opening 32. In this manner, there is a transition region between the first display region 11 and the second display region 12, the phenomenon of uneven display brightness in the visual effect between the first display region 11 and the second display region 12 is alleviated, and the display effect of the display panel is improved.

The area of the first pixel opening 31, the area of the second pixel opening 32 and the area of the third pixel opening 36 may be configured according to actual requirements. For example, the area of the first pixel opening 31 is ½ of the area of the second pixel opening 32, and the area of the third pixel opening 36 is ¾ of the area of the second pixel opening 32. As long as the area of the third pixel opening 36 is configured to be greater than the area of the first pixel opening 31 and less than the area of the second pixel opening 32. This is not limited in this embodiment of the present application.

FIG. 31 is a section view illustrating a partial structure of another display panel according to an embodiment of the present application. As shown in FIG. 31, optionally, the second display region 12 also includes third pixel circuits 122. The third pixel circuit 122 is configured to drive the first sub-pixel 111 to emit light. The first display region 11 also includes a leakage current suppression structure 112. A fixed potential signal is transmitted on the leakage current suppression structure 112.

As shown in FIG. 31, the third pixel circuits 122 driving the first sub-pixels 111 to emit light are disposed in the second display region 12 to reduce the number of pixel circuits in the first display region 11, thereby improving the transmittance of the first display region 11. In this manner, the sensor disposed at the first display region 11 can receive more external natural light, and the service performance of the sensor is improved.

At the same time, with continued reference to FIG. 31, the leakage current suppression structure 112 is disposed in the first display region 11 to suppress the leakage current on a first sub-pixel 111 in the first display region 11. In this manner, the problem of a leakage current caused by the absence of a pixel circuit below the first sub-pixel 111 is alleviated. The leakage current suppression structure 112 may be disposed on the same layer as any one or more metal layers (such as a gate layer 73 and a source and drain layer 75) in the array substrate 34 to reduce the disposition of one conductive layer. In this manner, an object of reducing the production cost and the thickness of the display panel is achieved. Moreover, the leakage suppressing structure 112 and the metal layer on the same layer are made of the same material. Thus, the leakage current suppression structure 112 and the metal layer on the same layer may be prepared in the same process, thereby shortening the process time.

With continued reference to FIGS. 8, 15, 21, 24 and 26, optionally, a winding design may be applied to the first scan line 51, the second scan line 52, the light emission control signal line 53, the first power signal line 54, the second power signal line 55, the reference voltage line 56 and the data line 57 so that wires between first pixel circuits 23 can form a light-transmissive region having a large area. In this manner, the sensor disposed at the first display region 11 can receive a large area of external natural light, and the service performance of the sensor is improved.

Other function film layers in the display panel may be configured according to actual requirements. For example, with reference to FIGS. 13 to 31, an organic light-emitting diode (OLED) display panel is used as an example. The display panel provided by this embodiment of the present application also includes an array substrate 34. The array substrate 34 includes a substrate 341 and a pixel circuit layer disposed on a side of the substrate 341. The pixel circuit layer includes a buffer layer 342, an active layer 71, a gate insulating layer 72, a gate layer 73, an interlayer insulating layer 74, a source and drain layer 75 and a planarization layer 76 which are stacked on the side of the substrate 341. The buffer layer 342 can play a role of shock proofing, buffering and isolation.

With continued reference to FIGS. 3 to 31, optionally, the display panel provided by this embodiment of the present application also includes a polarizer 77 and a protective cover plate 78 that are sequentially located on the side of a first sub-pixel 111 away from the substrate 341. This is not limited in this embodiment of the present application.

The sub-pixel arrangement, the pixel circuit structure and the pixel circuit arrangement in any preceding embodiment are merely examples. In other embodiments, the sub-pixel arrangement, the pixel circuit structure and the pixel circuit arrangement may be configured according to actual requirements. This is not limited in this embodiment of the present application.

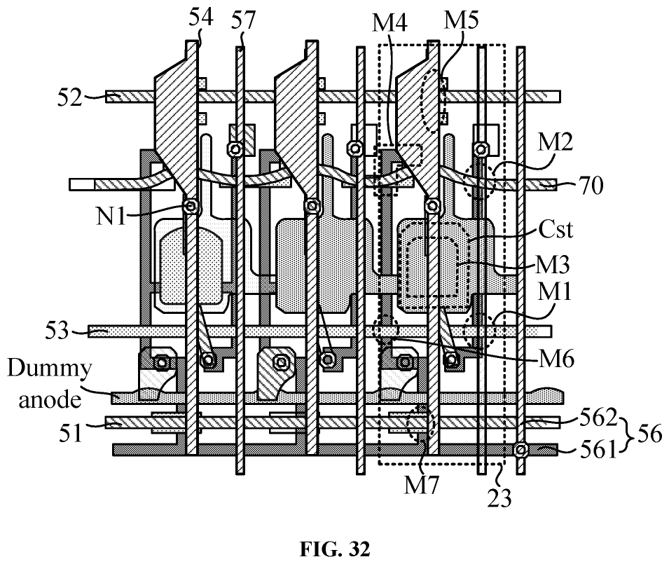

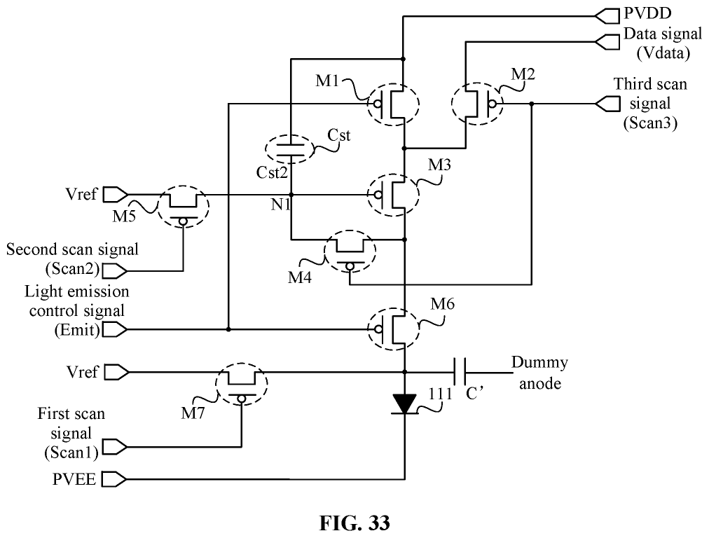

For example, FIG. 32 is a diagram illustrating the structure of another first pixel circuit according to an embodiment of the present application. FIG. 33 is a diagram of circuit elements of another first pixel circuit according to an embodiment of the present application. As shown in FIGS. 32 and 33, for example, the first pixel circuit 23 is a 7T1C pixel circuit (seven transistors and one storage capacitor). The display panel may include a first scan line 51, a second scan line 52, a third scan line 70, a light emission control signal line 53, a first power signal line 54, a reference voltage line 56 and a data line 57. Scan1 is a first scan signal input to the first scan line 51. Scan2 is a second scan signal input to the second scan line 52. Scan3 is a third scan signal input to the third scan line 70. Emit is a light emission control signal input to the light emission control signal line 53. Vdata is a data signal input to the data line 57. Vref is a reference voltage signal input to the reference voltage line 56. PVDD is a first power signal input to the first power signal line 54. PVEE is a second power signal for forming the current loop of a light-emitting element.

With continued reference to FIGS. 32 and 33, the first pixel circuit 23 may include a first light emission control transistor M1, a data signal write transistor M2, a drive transistor M3, an additional transistor M4, a memory cell reset transistor M5, a second light emission control transistor M6, a light-emitting reset transistor M7, a storage capacitor Cst and an additional capacitor C′. Pixel circuits shown in FIGS. 32 and 33 differ from pixel circuits shown in FIGS. 17 and 18 in that the reference voltage line 56 includes a first reference voltage line 561 and a second reference voltage line 562 that are electrically connected to each other and disposed in different layers. The extension direction of the first reference voltage line 561 is the same as the extension direction of the first scan line 51, the extension direction of the second scan line 52 and the extension direction of the third scan line 70. The extension direction of the second reference voltage line 562 is the same as the extension direction of the data line 57. In this manner, the voltage drop on the reference voltage line 56 may be reduced, and it is ensured that reference voltages at different positions are the same or similar. The first reference voltage line 561 and the active layer in a transistor may be disposed on the same layer. The second reference voltage line 562 and the data line 57 may be disposed on the same layer. With continued reference to FIGS. 32 and 33, the pixel circuits shown in FIGS. 32 and 33 also differ from the pixels circuit shown in FIGS. 17 and 18 in that scan lines and the gates of transistors are electrically connected to each other and are disposed in different layers. The film layer in which a scan line is located may be located on the side, away from the substrate, of the film layer in which the gate is located. With continued reference to FIGS. 32 and 33, the pixel circuits shown in FIGS. 32 and 33 also differ from the pixels circuit shown in FIGS. 17 and 18 in that a dummy anode is added. The additional capacitor C′ is formed between the dummy anode and the drain of the light-emitting reset transistor M7. The dummy anode and a substrate of the storage capacitor Cst may be disposed in the same layer. As shown in FIG. 32, the first power signal line 54 covers the first node N1. Since the PVDD signal transmitted on the first power signal line 54 is a fixed potential signal, the potential of the node N1 may be ensured to be stable and prevented from being affected by other signals. In this manner, the drive transistor M3 is ensured to operate normally. A capacitor substrate of the storage capacitor Cst includes a branch located between the data line 57 and the first node N1. Since the capacitor substrate and the first power signal line 54 are electrically connected through a punched via (not shown in the figure), a fixed potential signal PVDD signal is also transmitted on the capacitor substrate. In this manner, the capacitor substrate including the branch may prevent the potential of the first node N1 being affected by a changed data signal. Moreover, the stability of the potential of the first node N1 is ensured, and the drive transistor M3 is ensured to operate normally.

Different film layers may be connected by punched vias. Only part of connection vias is shown in FIG. 32, and part of the connection vias is not shown.

The pixel circuits shown in FIGS. 32 and 33 are used as an example to describe another arrangement relationship between a pixel circuit and a sub-pixel.

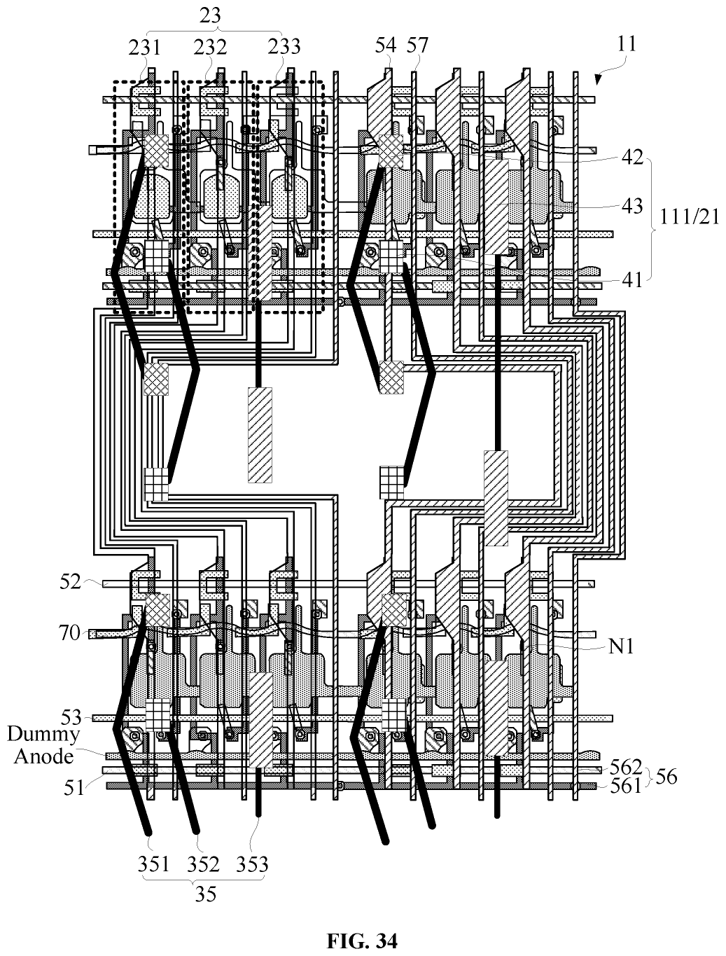

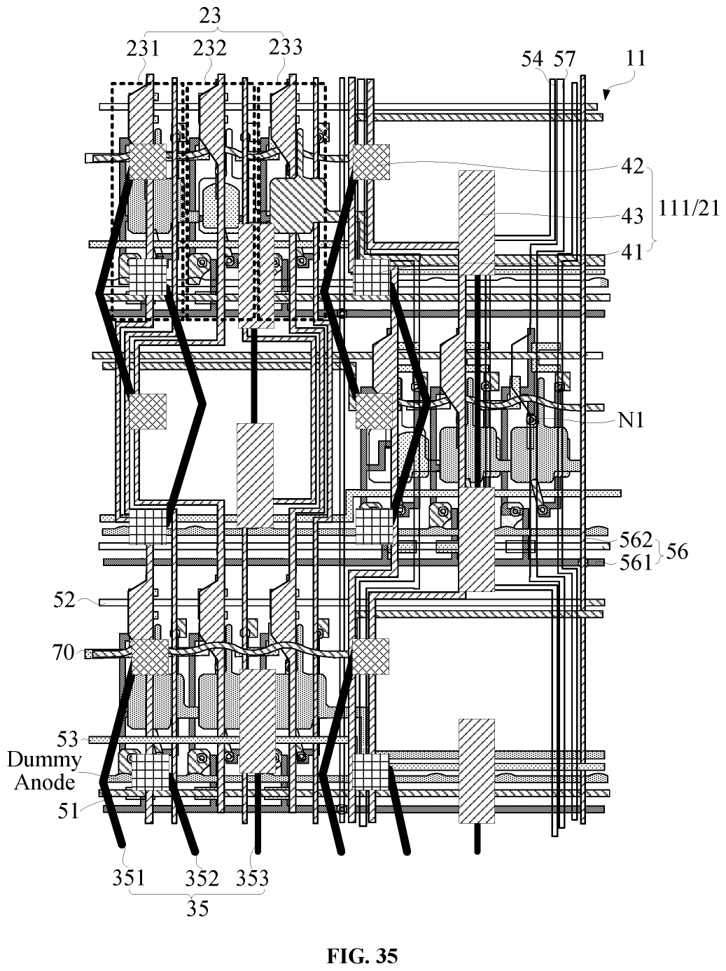

FIG. 34 is a section view illustrating a partial structure of another display panel according to an embodiment of the present application. FIG. 35 is a section view illustrating a partial structure of another display panel according to an embodiment of the present application. As shown in FIGS. 34 and 35, one first pixel circuit 23 is configured to drive two first sub-pixels 111 of the same color to emit light to reduce the number of first pixel circuits 23, thereby improving the transmittance of the first display region 11. In this manner, the sensor disposed at the first display region 11 can receive more external natural light, and the service performance of the sensor is improved.

The number of first sub-pixels 111 driven by one first pixel circuit 23 may be configured according to actual requirements. For example, 1 is used to drive 2 (that is, one first pixel circuit 23 is used to drive two first sub-pixels 111), 1 is used to drive 3, and 1 is used to drive 4 to reduce the number of first pixel circuits 23. This is not limited in this embodiment of the present application.

With continued reference to FIGS. 32 to 35, optionally, the gate of the drive transistor M3 and a capacitor plate of the storage capacitor Cst are electrically connected at the first node N1. In the thickness direction of the display panel, the transparent conductive layer 35 does not overlap the first node N1.

In this embodiment, the transparent conductive layer 35 is configured not to overlap the first node N1 in the thickness direction of the display panel to prevent the transparent conductive layer 35 from forming parasitic capacitance at the position of the first node N1 and affecting the gate voltage of the drive transistor M3, thereby ensuring the brightness of the first sub-pixel 111. In this manner, the brightness difference between the first display region 11 and the second display region 12 is reduced, the phenomenon of uneven display brightness in the visual effect of the first display region 11 and the second display region 12 is alleviated, and the display effect of the display panel is improved.

The technical solutions in any preceding embodiment may be applied to the display panel shown in FIGS. 32 to 35 and have corresponding technical effects. The explanations of the structures and terms that are the same as or corresponding to those in the preceding embodiments are not repeated here and may be configured according to actual requirements.

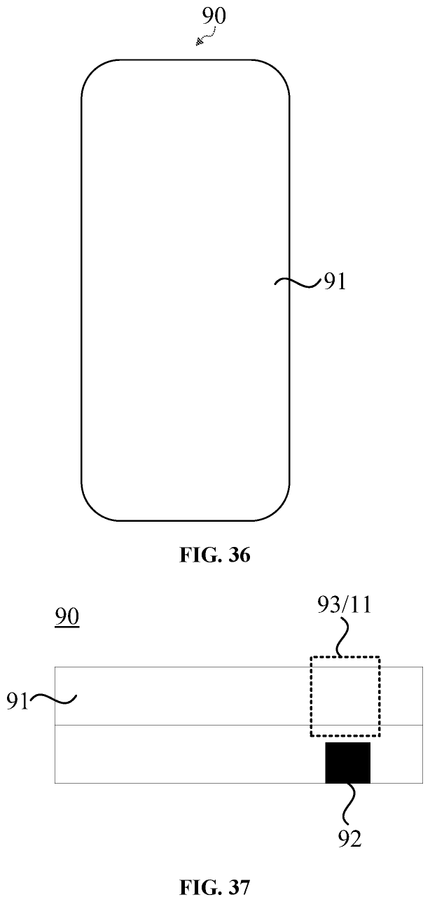

Based on the same concept, an embodiment of the present application also provides a display device. FIG. 36 is a diagram illustrating the structure of a display device according to an embodiment of the present application. As shown in FIG. 36, the display device 90 includes the display panel 91 according to any embodiment of the present application. Therefore, the display device 90 provided in this embodiment of the present application has the technical effects of the technical solutions in any preceding embodiment. The explanations of the structures and terms that are the same as or corresponding to those in the preceding embodiments are not repeated here. The display device 90 provided by this embodiment of the present application may be a phone shown in FIG. 16 or may be any electronic product having a display function, including but not limited to the following categories: a television, a laptop, a desktop display, a tablet computer, a digital camera, a smart bracelet, smart glasses, a vehicle-mounted display, medical equipment, industrial control equipment and touch interactive terminal. This is not specially limited in this embodiment of the present application.

FIG. 37 is a section view illustrating the structure of a display device according to an embodiment of the present application. As shown in FIGS. 36 and 37, optionally, the display device provided by this embodiment of the present application also includes a sensor 92. The display panel 91 also includes a sensor reserved region 93. The sensor 92 is disposed in the sensor reserved region 93. The first display region 11 also serves as the sensor reserved region 93.

The sensor 92 may include any photosensitive element such as a camera and an infrared sensor. With the configuration in which the sensor 92 is configured to correspond to the first display region 11; the first-type first sub-pixels 21 are disposed in the first display region 11; the first-type second sub-pixels 22 having the same emitted colors as the emitted colors of the first-type first sub-pixels 21 are disposed in the second display region 12; and the area of the first anode 211 of a first-type first sub-pixel 21 is configured to be less than the area of the second anode 221 of a first-type second sub-pixel 22, the spacing between the first anodes 211 of adjacent first-type first sub-pixels 21 is increased. In this manner, the problem of leakage emission of an adjacent first sub-pixel 111 is alleviated, the image display effect of the display panel is improved, and the service life of the display panel is prolonged.

1. A display panel, comprising a first display region and a second display region, wherein the first display region comprises a plurality of first sub-pixels, and the second display region comprises a plurality of second sub-pixels;
a first sub-pixel of the plurality of first sub-pixels comprises a first-type first sub-pixel, a second sub-pixel of the plurality of second sub-pixels comprises a first-type second sub-pixel, and an emitted color of the first-type first sub-pixel is the same as an emitted color of the first-type second sub-pixel;
the first-type first sub-pixel comprises a first anode, and the first-type second sub-pixel comprises a second anode; and
an area of the first anode is less than an area of the second anode.

2. The display panel according to claim 1, wherein the first-type first sub-pixel further comprises a first pixel opening, and the first-type second sub-pixel further comprises a second pixel opening;
the first anode comprises a first anode effective region, and a vertical projection of the first pixel opening on a plane where the first anode is located covers the first anode effective region;
the second anode comprises a second anode effective region, and a vertical projection of the second pixel opening on a plane where the second anode is located covers the second anode effective region; and
an area of the first anode effective region is less than an area of the second anode effective region.

3. The display panel according to claim 1, wherein the first-type first sub-pixel further comprises a first pixel opening, and the first-type second sub-pixel further comprises a second pixel opening;
the first anode comprises a first anode ineffective region, and a vertical projection of the first pixel opening on a plane where the first anode is located does not overlap the first anode ineffective region;
the second anode comprises a second anode ineffective region, and a vertical projection of the second pixel opening on a plane where the second anode is located does not overlap the second anode ineffective region; and
an area of the first anode ineffective region is less than an area of the second anode ineffective region.

4. The display panel according to claim 1, wherein the first display region further comprises a plurality of first pixel units, and a first pixel unit of the plurality of first pixel units comprises at least two first-type first sub-pixels having different emitted colors;
the second display region further comprises a plurality of second pixel units, and a second pixel unit of the plurality of second pixel units comprises at least two first-type second sub-pixels having different emitted colors; and
a distance between two adjacent first-type first sub-pixels in a same first pixel unit of the plurality of first pixel units is L1, and a distance between two adjacent first-type second sub-pixels in a same second pixel unit of the plurality of second pixel units is L2, wherein (L1−L2)/L2≥5%.

5. The display panel according to claim 1, wherein a pixel distribution density of the plurality of first sub-pixels is greater than or equal to a pixel distribution density of the plurality of second sub-pixels.

6. The display panel according to claim 5, wherein the pixel distribution density of the plurality of first sub-pixels is equal to the pixel distribution density of the plurality of second sub-pixels.

7. The display panel according to claim 6, wherein the first-type first sub-pixel further comprises a first pixel opening, and the first-type second sub-pixel further comprises the second pixel opening;
the first anode comprises a first anode effective region, and a vertical projection of the first pixel opening on a plane where the first anode is located covers the first anode effective region;
the second anode comprises the second anode effective region, and the vertical projection of the second pixel opening on a plane where the second anode is located covers the second anode effective region;
an area of the first anode effective region is less than an area of the second anode effective region; and
an area of the first pixel opening is less than or equal to an area of the second pixel opening.

8. The display panel according to claim 7, wherein the first sub-pixel comprises a first red sub-pixel, a first green sub-pixel and a first blue sub-pixel; and
the first-type first sub-pixel comprises at least one of the first red sub-pixel or the first blue sub-pixel.

9. The display panel according to claim 8, wherein the first-type first sub-pixel further comprises a first green sub-pixel.

10. The display panel according to claim 9, wherein the first display region further comprises a plurality of first pixel circuits, the second display region further comprises a plurality of second pixel circuits, a first pixel circuit of the plurality of first pixel circuits is configured to drive a first sub-pixel to emit light, and a second pixel circuit of the plurality of second pixel circuits is configured to drive a second sub-pixel to emit light; and the second sub-pixel comprises a second green sub-pixel; and
the first pixel circuits comprises a first sub-pixel circuit configured to drive the first green sub-pixel to emit light, and the second pixel circuit comprises a second sub-pixel circuit configured to drive the second green sub-pixel to emit light; and
a channel width-to-length ratio of a drive transistor in the first sub-pixel circuit is greater than a channel width-to-length ratio of a drive transistor in the second sub-pixel circuit.

11. The display panel according to claim 10, wherein the first sub-pixel circuit is configured to drive at least two first green sub-pixels to emit light.

12. The display panel according to claim 11, wherein two first sub-pixel circuits are configured to drive four first green sub-pixels to emit light.

13. The display panel according to claim 10, wherein the first pixel circuit further comprises a third sub-pixel circuit and a fourth sub-pixel circuit, wherein the third sub-pixel circuit is configured to drive the first red sub-pixel to emit light, and the fourth sub-pixel circuit is configured to drive the first blue sub-pixel to emit light; and
the third sub-pixel circuit is configured to drive at least two first red sub-pixels to emit light; or the fourth sub-pixel circuit is configured to drive at least two first blue sub-pixels to emit light; or the third sub-pixel circuit is configured to drive at least two first red sub-pixels to emit light, and the fourth sub-pixel circuit is configured to drive at least two first blue sub-pixels to emit light.

14. The display panel according to claim 8, wherein the first display region further comprises a plurality of first pixel circuits, wherein a first pixel circuit of the plurality of first pixel circuits is configured to drive the first sub-pixel to emit light;
the plurality of first pixel circuits comprises a first sub-pixel circuit, a third sub-pixel circuit and a fourth sub-pixel circuit, wherein the first sub-pixel circuit is configured to drive the first green sub-pixel to emit light, the third sub-pixel circuit is configured to drive the first red sub-pixel to emit light, and the fourth sub-pixel circuit is configured to drive the first blue sub-pixel to emit light; and
at least one of the first sub-pixel circuit, the third sub-pixel circuit or the fourth sub-pixel circuit is configured to drive at least two first sub-pixels electrically connected to the at least one of the first sub-pixel circuit, the third sub-pixel circuit or the fourth sub-pixel circuit to emit light.

15. The display panel according to claim 11, 13 or H, wherein at least two first sub-pixels driven by a same first pixel circuit of the plurality of first pixel circuits are electrically connected by a transparent conductive layer.

16. The display panel of claim 14, wherein
the first sub-pixel circuit is configured to drive at least two first sub-pixels electrically connected to the first sub-pixel circuit to emit light, the third sub-pixel circuit is configured to drive at least two first sub-pixels electrically connected to the third sub-pixel circuit to emit light, and the fourth sub-pixel circuit is configured to drive at least two first sub-pixels electrically connected to the fourth sub-pixel circuit to emit light;
the first sub-pixel comprises a first-color light-emitting sub-pixel, a second-color light-emitting sub-pixel and a third-color light-emitting sub-pixel;
at least two first-color light-emitting sub-pixels driven by a same pixel circuit are electrically connected by a first transparent conductive layer; at least two second-color light-emitting sub-pixels driven by a same pixel circuit are electrically connected by a second transparent conductive layer; and at least two third-color light-emitting sub-pixels driven by a same pixel circuit are electrically connected by a third transparent conductive layer;
the display panel further comprises a substrate, wherein on a plane where the substrate is located, a vertical projection of the first transparent conductive layer overlaps a vertical projection of a first pixel circuit configured to drive the first-color light-emitting sub-pixel to emit light; or on a plane where the substrate is located, a vertical projection of the first transparent conductive layer does not overlap a vertical projection of the first pixel circuit;
a vertical projection of at least part of the second transparent conductive layer on the plane where the substrate is located overlaps a vertical projection of at least one of the following on the plane where the substrate is located: a first pixel circuit configured to drive the first-color light-emitting sub-pixel or a first pixel circuit configured to drive the third-color light-emitting sub-pixel to emit light; and
a vertical projection of at least part of the third transparent conductive layer on the plane where the substrate is located overlaps a vertical projection of at least one of the following on the plane where the substrate is located: the first pixel circuit configured to drive the first-color light-emitting sub-pixel or a first pixel circuit configured to drive the second-color light-emitting sub-pixel to emit light.

17. The display panel according to claim 16, wherein an extension length of the first transparent conductive layer is less than an extension length of the second transparent conductive layer and an extension length of the third transparent conductive layer.

18. The display panel according to claim 17, wherein a line width of the first transparent conductive layer is less than a line width of the second transparent conductive layer and a line width of the third transparent conductive layer.

19. The display panel according to claim 15, wherein the first pixel circuit comprises a drive transistor and a storage capacitor, and a gate of the drive transistor and a capacitor plate of the storage capacitor are electrically connected to each other at a first node; and
the display panel further comprises a substrate, wherein a vertical projection of the transparent conductive layer on a plane where the substrate is located does not overlap a vertical projection of the first node on the plane where the substrate is located.

20. The display panel according to claim 15, wherein the at least two first sub-pixels driven by the same first pixel circuit comprise a first sub-pixel A and a first sub-pixel B; and
a first anode of the first sub-pixel A is electrically connected to the first pixel circuit through a via, and the first anode of the first sub-pixel A is electrically connected to a first anode of the first sub-pixel B by the transparent conductive layer.

21. The display panel according to claim 20, wherein the plurality of first pixel circuits are arranged in an array and comprise a plurality of first pixel circuit groups, and a first pixel circuit group of the plurality of first pixel circuit groups comprises at least two adjacent first pixel circuit columns; and
the display panel further comprises a substrate, wherein a vertical projection of the first sub-pixel A on a plane where the substrate is located overlaps a vertical projection of the first pixel circuit group on the plane where the substrate is located; and a vertical projection of at least part of the first sub-pixel B on the plane where the substrate is located overlaps a vertical projection of a gap between two adjacent first pixel circuit groups of the plurality of first pixel circuit groups on the plane where the substrate is located.

22. The display panel according to claim 20, wherein the plurality of first pixel circuits are arranged in an array and comprise a plurality of second pixel circuit groups, one second pixel circuit group of the plurality of second pixel circuit groups comprises at least two adjacent first pixel circuit rows, and two adjacent first pixel circuit rows in the one second pixel circuit group are staggered in a row direction, wherein the row direction is an extension direction of the at two adjacent first pixel circuit rows; and
the display panel further comprises a substrate, wherein on a plane where the substrate is located, a vertical projection of the first sub-pixel A overlaps a vertical projection of one second pixel circuit group of the plurality of second pixel circuit groups; and on the plane where the substrate is located, a vertical projection of at least part of the first sub-pixel B overlaps a vertical projection of a gap between two adjacent first pixel circuits in one first pixel circuit row of at least two adjacent first pixel circuit rows in one second pixel circuit group of the plurality of second pixel circuit groups.

23. The display panel according to claim 22, wherein the plurality of second pixel circuit groups comprise N second pixel circuit groups, wherein N denotes a positive integer;
each second pixel circuit group of the N second pixel circuit groups comprises M sub-pixel circuit groups, and an mth sub-pixel circuit group of the M sub-pixel circuit groups comprises an mth first pixel circuit in a first pixel circuit row in a same second pixel circuit group of the N second pixel circuit groups and an mth first pixel circuit in a second first pixel circuit row in the same second pixel circuit group, wherein M denotes a positive integer, and 1≤m≤M; and
the first display region further comprises M first data signal lines,
wherein an mth first data signal line of the M first data signal lines is configured to provide data signals for two first pixel circuits in an (m+n−1)th sub-pixel circuit group in an nth second pixel circuit group of the N second pixel circuit groups, wherein 1≤n≤N.

24. The display panel according to claim 23, wherein a first data signal line of the M first data signal lines comprises a plurality of first line segments and a plurality of second line segments alternately connected, wherein
an extension direction of a first line segment of the plurality of first line segments is parallel to an extension direction of the at least two adjacent first pixel circuit columns, and an extension direction of a first line segment of the plurality of second line segments intersects the extension direction of the at least two adjacent first pixel circuit columns; and
an extension length of the first line segment is greater than an extension length of the second line segment.

25. The display panel according to claim 22, wherein the plurality of second pixel circuit groups comprise N second pixel circuit groups, wherein N denotes a positive integer;
each second pixel circuit group of the N second pixel circuit groups comprises M sub-pixel circuit groups, and an mth sub-pixel circuit group of the M sub-pixel circuit groups comprises an mth first pixel circuit in a first pixel circuit row in a same second pixel circuit group of the N second pixel circuit groups and an mth first pixel circuit in a second first pixel circuit row in the same second pixel circuit group, wherein M denotes a positive integer, and 1≤m≤M; and
the first display region further comprises M first voltage signal lines,
wherein an mth first voltage signal line of the M first voltage signal lines is configured to provide voltage signals for two first pixel circuits in an (m+n−1)th sub-pixel circuit group in an nth second pixel circuit group of the N second pixel circuit groups, wherein 1≤n≤N.

26. The display panel according to claim 25, wherein a first voltage signal line of the M first voltage signal lines comprises a plurality of third line segments and a plurality of fourth line segments alternately connected,
wherein an extension direction of a third line segment of the plurality of third line segments is parallel to an extension direction of the at least two adjacent first pixel circuit columns, and an extension direction of a fourth line segment of the plurality of fourth line segments intersects the extension direction of the at least two adjacent first pixel circuit columns; and
wherein an extension length of the third line segment is greater than an extension length of the fourth line segment.

27. The display panel according to claim 5, wherein the first display region further comprises a plurality of first pixel circuits, and the first pixel circuit of the plurality of first pixel circuits is configured to drive the first sub-pixel to emit light;
the first pixel circuit comprises a first sub-pixel circuit, a third sub-pixel circuit and a fourth sub-pixel circuit, and the first sub-pixels comprises a first red sub-pixel, a first green sub-pixel and a first blue sub-pixel, wherein the first sub-pixel circuit is configured to drive the first green sub-pixel to emit light, the third sub-pixel circuit is configured to drive the first red sub-pixel to emit light, and the fourth sub-pixel circuit is configured to drive the first blue sub-pixel to emit light; and
at least one of the first sub-pixel circuit, the third sub-pixel circuit or the fourth sub-pixel circuit is configured to drive at least two first sub-pixels electrically connected to the at least one of the first sub-pixel circuit, the third sub-pixel circuit or the fourth sub-pixel circuit to emit light; and
the first display region further comprises brightness adjustment sub-pixels, wherein a brightness adjustment sub-pixel of the brightness adjustment sub-pixels is electrically connected to at least two first sub-pixels of a same color; and the first sub-pixel circuit is configured to drive at least two first sub-pixels electrically connected to the first sub-pixel circuit and a brightness adjustment sub-pixel electrically connected to the first sub-pixel circuit, the third sub-pixel circuit is configured to drive at least two first sub-pixels electrically connected to the third sub-pixel circuit and a brightness adjustment sub-pixel electrically connected to the third sub-pixel circuit, or the fourth sub-pixel circuit is configured to drive at least two first sub-pixels electrically connected to the fourth sub-pixel circuit and a brightness adjustment sub-pixel electrically connected to the fourth sub-pixel circuit.

28. The display panel according to claim 27, wherein the first display region comprises a plurality of repeated sub-pixel units and the brightness adjustment sub-pixel is located in a repeated sub-pixel unit of the plurality of repeated sub-pixel units.

29. The display panel according to claim 28, wherein the brightness adjustment sub-pixel comprise a first brightness adjustment sub-pixel and a second brightness adjustment sub-pixel, and the display panel further comprises a substrate, wherein on a plane where the substrate is located, a vertical projection of one of the first brightness adjustment sub-pixel overlaps a vertical projection of the first pixel circuit; and on the plane where the substrate is located, a vertical projection of the second brightness adjustment sub-pixel overlaps a vertical projection of a gap between two adjacent first pixel circuits of the plurality of first pixel circuits.

30. The display panel according to claim 29, wherein in a first direction, the first brightness adjustment sub-pixel is located between two sub-pixels that are in a same repeated sub-pixel unit and that have an emitted color different from an emitted color of the first brightness adjustment sub-pixel;
in the first direction, the second brightness adjustment sub-pixel is located between two sub-pixels that are between two adjacent repeated sub-pixel units and that have an emitted color different from an emitted color of the second brightness adjustment sub-pixel; and
the display panel further comprises data lines, and the first direction is parallel to an extension direction of the data lines.

31. The display panel according to claim 27, wherein at least two first sub-pixels and a brightness adjustment sub-pixel which are driven by the same first pixel circuit are sequentially arranged in a second direction, and in the second direction, the brightness adjustment sub-pixel is located between the at least two first sub-pixels; and
the display panel further comprises data lines, and the second direction intersects an extension direction of the data lines.

32. The display panel according to claim 28, wherein the brightness adjustment sub-pixel comprises a first brightness adjustment sub-pixel and a second brightness adjustment sub-pixel, and at least two first sub-pixels and a brightness adjustment sub-pixel which are driven by the first pixel circuit form one sub-pixel unit group; and
the sub-pixel unit group comprises a first sub-pixel unit groups and a second sub-pixel unit group, wherein the first sub-pixel unit group comprises the first brightness adjustment sub-pixel, and the second sub-pixel unit group comprises the second brightness adjustment sub-pixel; and
the display panel further comprises data lines, wherein a first sub-pixel unit group and a second sub-pixel unit group that are adjacent in a second direction share a same data line of the data lines, wherein the second direction intersects an extension direction of the data lines.

33. The display panel according to claim 27, wherein the brightness adjustment sub-pixel comprise a green sub-pixel; and
the first sub-pixel circuit is configured to drive at least two first green sub-pixels electrically connected to the first sub-pixel circuits and a brightness adjustment sub-pixel electrically connected to the first sub-pixel circuit to emit light.

34. The display panel according to claim 27, wherein the brightness adjustment sub-pixel is electrically connected to at least two first sub-pixels of the same color by a transparent conductive layer.

35. The display panel according to claim 5, wherein the second display region further comprises third pixel circuits configured to drive the plurality of first sub-pixels to emit light; and
the first display region further comprises a leakage current suppression structure, and a fixed potential signal is transmitted on the leakage current suppression structure.

36. The display panel according to claim 1, further comprising a third display region located between the first display region and the second display region, wherein
the third display region comprises a plurality of third sub-pixels, wherein
a third sub-pixel of the plurality of third sub-pixels comprises a first-type third sub-pixel, and an emitted color of the first-type third sub-pixel is the same as the emitted color of the first-type first sub-pixel and the emitted color of the first-type second sub-pixel; and
the first-type third sub-pixel comprises a third anode, and an area of the third anode is greater than the area of the first anode and less than the area of the second anode.

37. A display device, comprising a display panel, wherein the display panel further comprises a first display region and a second display region, wherein the first display region comprises a plurality of first sub-pixels, and the second display region comprises a plurality of second sub-pixels;
a first sub-pixel of the plurality of first sub-pixels comprises a first-type first sub-pixel, a second sub-pixel of the plurality of second sub-pixels comprises a first-type second sub-pixel, and an emitted color of the first-type first sub-pixel is the same as an emitted color of the first-type second sub-pixel;
the first-type first sub-pixel comprises a first anode, and the first-type second sub-pixel comprises a second anode; and
an area of the first anode is less than an area of the second anode.

38. The display device according to claim 37, further comprising a sensor,
wherein the display panel further comprises a sensor reserved region, the sensor is disposed in the sensor reserved region, and the first display region also serves as the sensor reserved region.
